(19) United States
(12) Patent Application Publication
(10) Pub. No.: US 2025/0338479 A1
(43) Pub. Date: Oct. 30, 2025

(54) SEMICONDUCTOR DEVICES

(71) Applicant: Samsung Electronics Co., Ltd., Suwon-si (KR)

(72) Inventors: Hongjun LEE, Suwon-si (KR); Keunnam KIM, Suwon-si (KR); Yongkwan KIM, Suwon-si (KR); Huijung KIM, Suwon-si (KR); Kiseok LEE, Suwon-si (KR); Inho CHA, Suwon-si (KR)

(73) Assignee: Samsung Electronics Co., Ltd., Suwon-si (KR)

(21) Appl. No.: 19/065,560

(22) Filed: Feb. 27, 2025

(30) Foreign Application Priority Data
Apr. 29, 2024 (KR) 10-2024-0056475

(51) Int. Cl. H10B 12/00

(52) U.S. Cl. CPC H10B 12/315; H10B 12/05

(57) ABSTRACT

A semiconductor device may include word lines extending in a first direction and spaced apart from each other in a second direction on a substrate, a channel layer on the word lines, bit lines contacting an upper surface of the channel layer and extending in the second direction, first conductive division lines on the channel layer and spaced apart from each other in the first direction, contact plugs contacting an upper surface of the channel layer and being spaced apart from each other in the first direction and the second direction, and capacitors on the contact plugs, respectively. The channel layer may be divided into channels electrically insulated from each other in the first direction by the first conductive division lines. The bit lines may be spaced apart from each other in the first direction. The first conductive division lines may extend in the second direction between the bit lines.

### CROSS-REFERENCE TO RELATED APPLICATION

This application claims priority under 35 U.S.C. § 119 to Korean Patent Application No. 10-2024-0056475 filed on Apr. 29, 2024 in the Korean Intellectual Property Office, the disclosure of which is hereby incorporated by reference in its entirety.

### TECHNICAL FIELD

Example embodiments of the present disclosure relate to a semiconductor device. More particularly, example embodiments of the present disclosure relate to a memory device including a vertical channel.

### DISCUSSION OF RELATED ART

A memory device including a vertical channel transistor has been developed in order to increase the integration degree of a semiconductor device. The vertical channel transistor may include a channel containing an oxide semiconductor material. When the semiconductor device is manufactured, the channel may be damaged.

### SUMMARY

Example embodiments provide a semiconductor device having improved electrical characteristics.

According to an example embodiment, a semiconductor device may include a substrate; word lines on the substrate, the word lines extending in a first direction, the first direction being parallel to an upper surface of the substrate, the word lines being spaced apart from each other in a second direction, the second direction being parallel to the upper surface of the substrate, and the second direction intersecting the first direction; a channel layer on the word lines; bit lines contacting an upper surface of the channel layer, the bit lines extending in the second direction and being spaced apart from each other in the first direction; first conductive division lines on the channel layer and spaced apart from each other in the first direction, the first conductive division lines extending in the second direction between the bit lines; contact plugs contacting the upper surface of the channel layer, the contact plugs being spaced apart from each other in the first direction and the second direction; and capacitors on the contact plugs, respectively. The channel layer may be divided into channels by the first conductive division lines and the channels may be electrically insulated from each other in the first direction.

According to an example embodiment, a semiconductor device may include a substrate; first conductive division lines on a substrate, the first conductive division lines extending in a first direction, the first direction being parallel to an upper surface of the substrate, the first conductive division lines being spaced apart from each other in a second direction, the second direction being parallel to the upper surface of the substrate, and the second direction intersecting the first direction; word lines spaced apart from each other in the second direction on the first conductive division lines, the word lines extending in the first direction; a channel layer on the first conductive division lines and the word lines; bit lines contacting an upper surface of the channel layer, the bit lines extending in the second direction, and the bit lines being spaced apart from each other in the first direction; contact plugs contacting the upper surface of the channel layer, the contact plugs being spaced apart from each other in the first direction and the second direction; and capacitors on the contact plugs, respectively. The channel layer may be divided into channels that may be electrically insulated from each other in the first direction by the first conductive division lines.

According to an example embodiment, a semiconductor device may include a substrate; first conductive division lines on the substrate, the first conductive division lines extending in a first direction, the first direction being parallel to an upper surface of the substrate, the first conductive division lines being spaced apart from each other in a second direction, the second direction being parallel to the upper surface of the substrate, and the second direction intersecting the first direction; word lines spaced apart from each other in the second direction on the first conductive division lines, the word lines extending in the first direction; a channel layer on the first conductive division lines and the word lines; bit lines contacting an upper surface of the channel layer, the bit lines extending in the second direction, and the bit lines being spaced apart from each other in the first direction; second conductive division lines spaced apart from each other in the first direction, the second conductive division lines extending in the second direction between the bit lines on the channel layer; contact plugs contacting the upper surface of the channel layer, the contact plugs being spaced apart from each other in the first direction and the second direction; and capacitors on the contact plugs, respectively. The channel layer may be divided into channels that may be electrically insulated from each other in the first direction and the second direction by the first conductive division lines and the second conductive division lines.

### BRIEF DESCRIPTION OF THE DRAWINGS

FIGS. 1 to 5 are a perspective view, a plan view and cross-sectional views illustrating a semiconductor device in accordance with example embodiments.

FIG. 6 is a circuit diagram illustrating a memory cell included in the semiconductor device, and FIG. 7 is a graph illustrating an operation of read for the memory cell.

FIGS. 8 to 78 are perspective views, plan views and cross-sectional views illustrating a method of manufacturing a semiconductor device in accordance with example embodiments.

FIG. 79 is a cross-sectional view illustrating a semiconductor device in accordance with example embodiments.

### DETAILED DESCRIPTION

The above and other aspects and features of the semiconductor devices and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, two directions among horizontal directions that are substantially parallel to an upper surface of a substrate, which may intersect each other, may be referred as first and second directions D1 and D2, respectively, and a direction substantially perpendicular to the upper surface of the substrate may be referred to as a third direction D3. In example embodiments, the first and second directions D1 and D2 may be substantially perpendicular to each other. Each of the first to third directions D1, D2 and D3 may include not only a direction shown in the drawing but also a direction that is inverse to the shown direction.

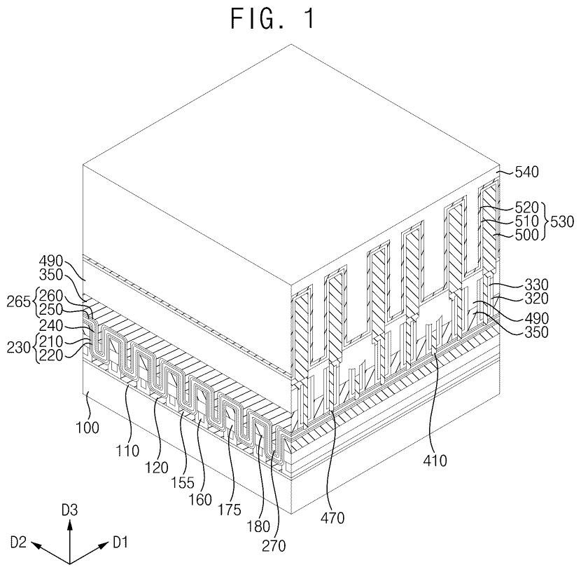

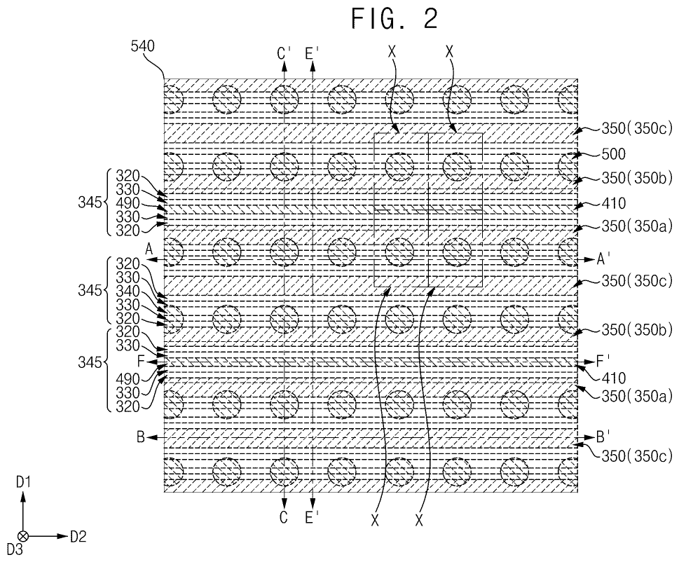

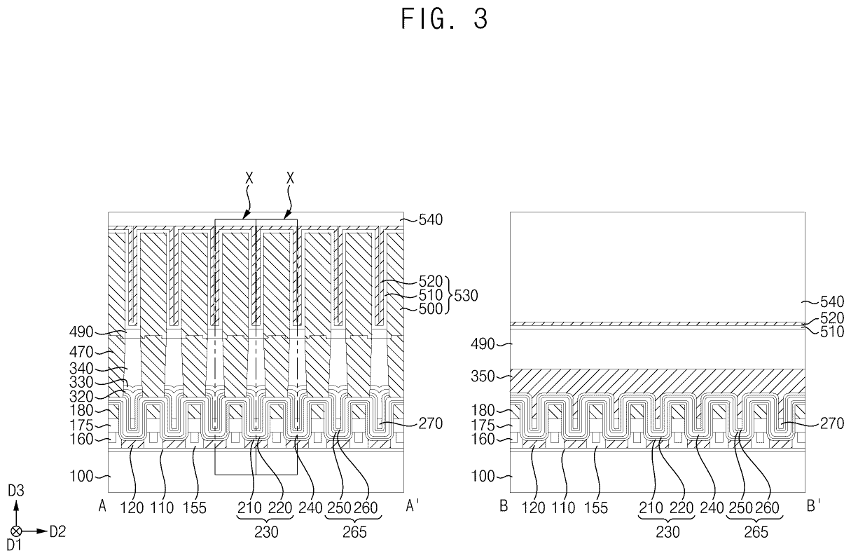

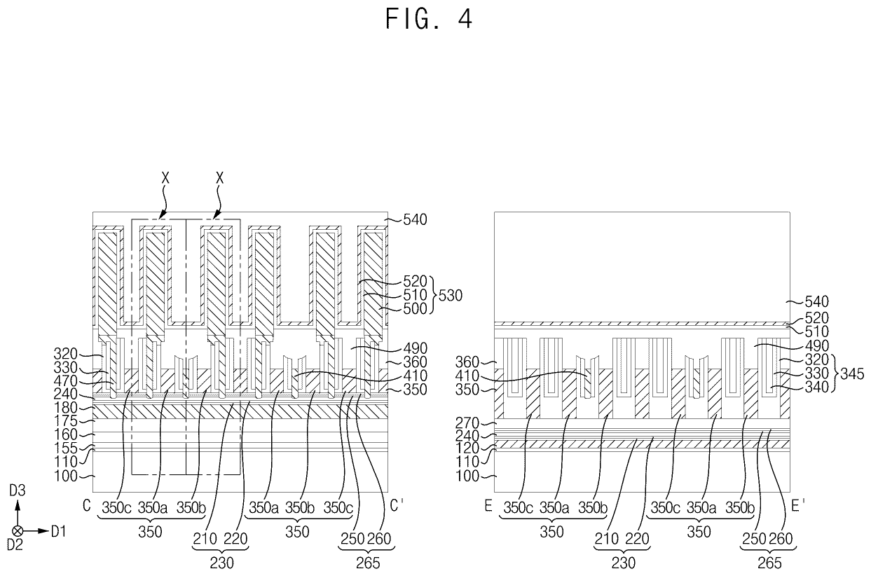

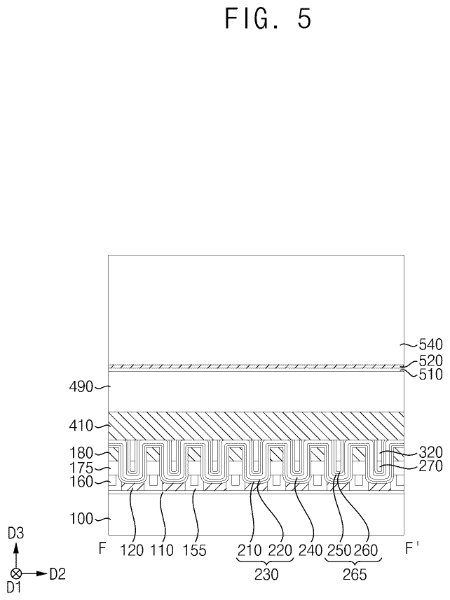

FIGS. 1 to 5 are a perspective view, a plan view and cross-sectional views illustrating a semiconductor device in accordance with example embodiments. Specifically, FIG. 1 is the perspective view, FIG. 2 is the plan view, FIG. 3 includes cross-sectional views taken along lines A-A′ and B-B′, respectively, of FIG. 2, FIG. 4 includes cross-sectional views taken along lines C-C′ and E-E′, respectively, of FIG. 2, and FIG. 5 is a cross-sectional view taken along line F-F′ of FIG. 2.

Referring to FIGS. 1 to 5, the semiconductor device may include first to fourth conductive lines 120, 180, 350 and 410, a channel layer 240, first and second gate insulation layer structures 230 and 265, a contact plug 470 and a capacitor 530.

The semiconductor device may further include a pad layer 110, an insulating interlayer pattern 160, first and second capping patterns 155 and 370, a first mold 175, first to fifth insulation patterns 270, 320, 330, 340 and 360, a ninth insulation layer 490, a sixth stack structure 345 and a plate electrode 540.

The substrate 100 may include silicon, germanium, silicon-germanium, or a III-V group compound semiconductor, e.g., GaP, GaAs, GaSb, etc. In example embodiments, the substrate 100 may be a silicon-on-insulator (SOI) substrate or a germanium-on-insulator (GOI) substrate.

The pad layer 110 may be disposed on the substrate 100, and may include an oxide, e.g., silicon oxide.

FIGS. 1 to 5 show that the pad layer 110 is disposed on the substrate 100, however, inventive concepts may not be limited thereto, and for example, a lower circuit pattern may be formed on the substrate 100, a lower insulating interlayer covering the lower circuit pattern may be formed on the substrate 100, and the pad layer 110 may not be formed. In this case, the semiconductor device may have a cell over periphery (COP) structure in which memory cells are disposed over peripheral circuit patterns. Alternatively, the semiconductor device may have a periphery over cell (POC) structure in which the peripheral circuit patterns are disposed on the memory cells.

The first conductive line 120 may be disposed on the pad layer 110, and may extend in the first direction D1. In example embodiments, a plurality of first conductive lines 120 may be spaced apart from each other in the second direction D2. As illustrated below, the first conductive line 120 may electrically divide in the second direction D2 the channel layer 240 extending in the second direction D2, and thus may also be referred to as a first conductive division line 120.

The first conductive line 120 may include a conductive material, e.g., a metal, a metal nitride, a metal silicide, etc.

The first capping pattern 155 may be disposed on the pad layer 110, and may extend in the first direction D1. In example embodiments, a plurality of first capping patterns 155 may be spaced apart from each other in the second direction D2. Each of the first capping patterns 155 may be disposed between and contact neighboring ones of the first conductive lines 120 in the second direction D2. In example embodiments, a vertical cross-sectional view in the second direction D2 may have a cup shape. The first capping pattern 155 may include an insulating nitride, e.g., silicon nitride.

The insulating interlayer pattern 160 may be disposed on the first capping pattern 155, and may extend in the first direction D1. In example embodiments, a plurality of insulating interlayer patterns 160 may be spaced apart from each other in the second direction D2. A sidewall in the second direction D2 and a lower surface of each of the insulating interlayer patterns 160 may be covered by the first capping pattern 155. The insulating interlayer pattern 160 may include an oxide, e.g., silicon oxide.

In example embodiments, an uppermost surface of the first capping pattern 155 and upper surface of the insulating interlayer pattern 160 may be substantially coplanar with each other.

The first mold 175 may be disposed on the first capping pattern 155 and the insulating interlayer pattern 160, and may extend in the first direction D1. In example embodiments, a plurality of first molds 175 may be spaced apart from each other in the second direction D2. The first mold 175 may include an oxide, e.g., silicon oxide.

The second conductive line 180 may be disposed on the first mold 175, and may extend in the first direction D1. In example embodiments, a plurality of second conductive lines 180 may be spaced apart from each other in the second direction D2. In example embodiments, the second conductive line 180 may serve as a word line of the semiconductor device, and may also be referred to as the word line.

The second conductive line 180 may include a conductive material, e.g., a metal, a metal nitride, a metal silicide, etc.

The first gate insulation layer structure 230, the channel layer 240 and the second gate insulation layer structure 265 may be sequentially stacked on an upper surface of the first conductive line 120, a sidewall in the second direction D2 of an upper portion of the first capping pattern 155, a sidewall in the second direction D2 of the first mold 175, and a sidewall in the second direction D2 and an upper surface of the second conductive line 180.

The first gate insulation layer structure 230 may include first and second gate insulation layers 210 and 220 sequentially stacked, and the second gate insulation layer structure 265 may include third and fourth gate insulation layers 250 and 260 sequentially stacked. The first gate insulation layer structure 230 and a first division gate electrode included in the first conductive division line 120 may form a first division gate structure, and the first gate insulation layer structure 230 and a gate electrode included in the word line 180 may form a gate structure.

Each of the first and third gate insulation layers 210 and 250 may include, e.g., silicon oxide, and each of the second and fourth gate insulation layers 220 and 260 may include a metal oxide, e.g., aluminum oxide.

In example embodiments, each of the first gate insulation layers 230 and the channel layer 240 may be disposed on the substrate 100, and a plurality of second gate insulation layer structures 265, each of which may extend in the second direction D2, may be spaced apart from each other in the first direction D1.

In example embodiments, the channel layer 240 may include an oxide semiconductor material. The oxide semiconductor material may include at least one of zinc tin oxide (ZTO), indium zinc oxide (IZO), zinc oxide (ZnOₓ), indium gallium zinc oxide (IGZO), indium gallium silicon oxide (IGSO), Indium oxide (InOₓ, In₂O₃), tin oxide (SnO₂), titanium oxide (TiOₓ), zinc oxide nitride (ZnₓO_{y}N_{z}), magnesium zinc oxide (MgₓZn_{y}O_{z}), indium zinc oxide (InₓZn_{y}Oₐ), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}O_{d}) a), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ), zinc tin oxide (ZnₓSn_{y}O_{z}), aluminum zine tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ) and indium gallium silicon oxide (InGaSiO).

The first insulation pattern 270 may be disposed on the second gate insulation layer structure 265, and may extend in the first direction D1. In example embodiments, a plurality of first insulation patterns 270 may be spaced apart from each other in the second direction D2. A sidewall in the second direction D2 and a lower surface of each of the first insulation patterns 270 may be covered by the second gate insulation layer structure 265, and an upper surface of each of the insulation patterns 270 may be lower than an uppermost surface of the second gate insulation layer structure 265. In example embodiments, the first insulation pattern 270 may at least partially overlap the first conductive line 120 in the third direction D3.

The first insulation pattern 270 may include an insulating nitride, e.g., silicon nitride.

The third conductive line 350 may extend in the second direction D2 on the second gate insulation layer structure 265 and the first insulation pattern 270, and a plurality of third conductive lines 350 may be spaced apart from each other in the first direction D1. In example embodiments, a height of a lower surface of the third conductive line 350 may periodically change in the second direction D2. That is, a lower surface of a portion of the third conductive line 350 on the first insulation pattern 270 may be lower than a lower surface of a portion of the third conductive line 350 on the second gate insulation layer structure 265. A height of an upper surface of the third conductive line 350 may be substantially constant in the second direction D2.

In example embodiments, the third conductive line 350 may include first to third sub conductive lines 350a, 350b and 350c, which may be alternately and repeatedly disposed in the first direction D1.

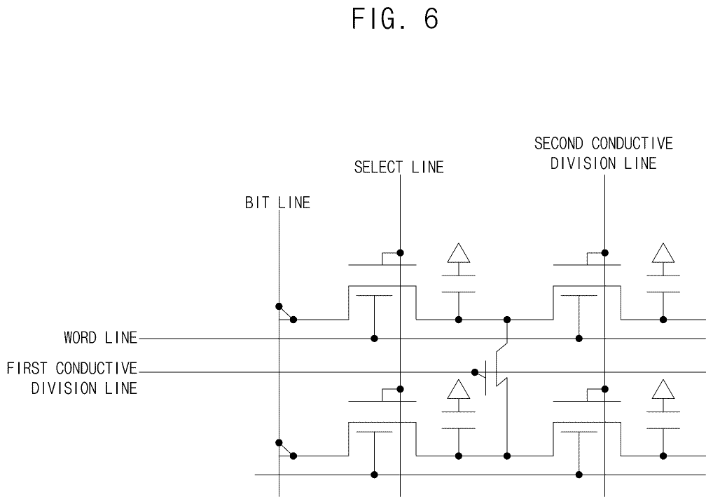

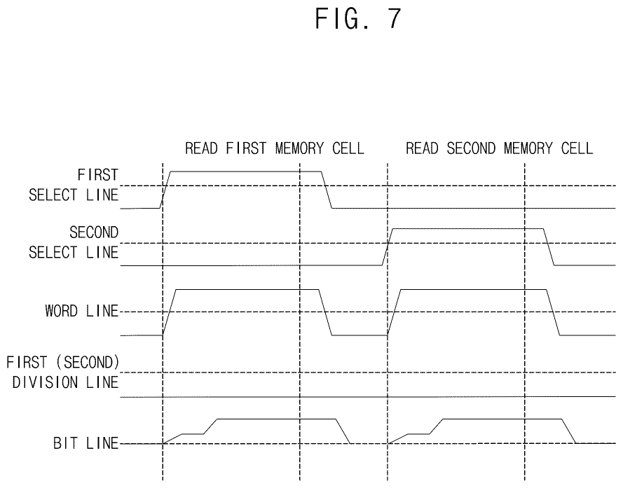

The first sub conductive line 350a may include a first back gate electrode of the semiconductor device, the second sub conductive line 350b may include a second back gate electrode of the semiconductor device, and the third sub conductive line 350c may include a second division gate electrode. The third sub conductive line 350c may electrically divide in the first direction D1 the channel layer 240 extending in the first direction D1, as illustrated below with reference to FIGS. 6 and 7, and thus may also be referred to as a second conductive division line 350c.

The second gate insulation layer structure 265 and the first back gate electrode included in the first sub conductive line 350a may form a first back gate structure, the second gate insulation layer structure 265 and the second back gate electrode included in the second sub conductive line 350b, and the second gate insulation layer structure 265 and the second division gate electrode included in the third sub conductive line 350c may form a second division gate structure.

The third conductive line 350 may include a conductive material, e.g., a metal, a metal nitride, a metal silicide, etc.

The fourth conductive line 410 may extend in the second direction D2 on the channel layer 240, the second gate insulation layer structure 265 and the first insulation pattern 270, and a plurality of fourth conductive lines 410 may be spaced apart from each other in the first direction D1. In example embodiments, the fourth conductive line 410 may contact uppermost surfaces of the channel layer 240 and the second gate insulation layer structure 265, that is, an upper surface of a portion of the channel layer 240 on the second conductive line 180 and an upper surface of a portion of the second gate insulation layer structure 265 adjacent thereto in the second direction D2.

In an example embodiment, a height of an upper surface and a height of a lower surface of the fourth conductive line 410 may be substantially constant in the second direction D2. In an example embodiment, the upper surface of the fourth conductive line 410 may be substantially coplanar with an upper surface of the third conductive line 350, however, inventive concepts may not be limited thereto.

In example embodiments, the fourth conductive line 410 may serve as a bit line of the semiconductor device, and thus may also be referred to as the bit line. In example embodiments, the fourth conductive line 410 may be disposed between neighboring ones of the first and second sub conductive lines 350a and 350b in the first direction D1.

The fourth conductive line 410 may include a conductive material, e.g., a metal, a metal nitride, a metal silicide, etc.

The sixth stack structure 345 may include second to fourth insulation patterns 320, 330 and 340 sequentially stacked on the second gate insulation layer structure 265 and the first insulation pattern 270. The sixth stack structure 345 may extend in the second direction D2, and a plurality of sixth stack structures 354 may be spaced apart from each other in the first direction D1.

In example embodiments, a lower surface of a portion of the sixth stack structure 345 on the first insulation pattern 270 may be lower than a lower surface of a portion of the sixth stack structure on the second gate insulation layer structure 265. Thus, a height of the lower surface of the sixth stack structure 345 may periodically change in the second direction D2.

The third insulation pattern 330 may cover a sidewall in the first direction D1 and a lower surface of the fourth insulation pattern 340, and the second insulation pattern 320 may cover an outer sidewall in the first direction D1 and a lower surface of the third insulation pattern 330. A vertical cross-section in the first direction D1 of each of the second and third insulation patterns 320 and 330 may have a cup shape.

In example embodiments, a thickness in the third direction D3 of a portion of the second insulation pattern 320 on the first insulation pattern 270 may be greater than a thickness in the third direction D3 of a portion of the second insulation pattern 320 on the second gate insulation layer structure 265.

In example embodiments, the fourth conductive line 410 may extend in the second direction D2 through a portion of the sixth stack structures 345 disposed in the first direction D1, particularly, a portion of the sixth stack structure 345 disposed between the first and second sub conductive lines 350a and 350b neighboring in the first direction D1. That is, the fourth conductive line 410 may extend through ones of the sixth stack structures 345 disposed in the first direction D1, which may be disposed at (3n)-th (n is a natural number) positions, e.g., third, sixth, ninth positions, etc., in the first direction D1 among the sixth stack structures 345.

The fourth conductive line 410 may extend entirely through the fourth insulation pattern 340, and may extend through a lower portion of the third insulation pattern 330 so that upper portions of respective opposite sidewalls in the first direction D1 of the fourth conductive line 410 may contact respective inner sidewalls in the first direction D1 of the third insulation pattern 330. Thus, each of the ones of the sixth stack structures 345 through which the fourth conductive line 410 extends, that is, each of the ones of the sixth stack structures 345 that are disposed at the (3n)—the positions among the sixth stack structures 345 disposed in the first direction D1 may not include the fourth insulation pattern 340 and may include only the second and third insulation patterns 320 and 330.

The fourth conductive line 410 may entirely extend through and contact a lower portion of a portion of the second insulation pattern 320 on the second gate insulation layer structure 265, and may partially extend through a lower portion of a portion of the second insulation pattern 320 on the first insulation pattern 270.

In example embodiments, an uppermost surface of each of the ones of the sixth stack structures 345 through which the fourth conductive line 410 extends, that is, an uppermost surface of each of the ones of the sixth stack structures 345 that are disposed at the (3n)—the positions among the sixth stack structures 345 disposed in the first direction D1 may be lower than uppermost surfaces of other ones of the sixth stack structures 345.

The second insulation pattern 320 may include, e.g., silicon oxycarbide (SiOC), the third insulation pattern 330 may include an insulating nitride, e.g., silicon nitride, and the fourth insulation pattern 340 may include, e.g., silicon oxide.

The contact plug 470 may extend through the sixth stack structure 345 and the second gate insulation layer structure 265, and may contact an upper surface of the channel layer 240. In example embodiments, a plurality of contact plugs 470 may be spaced apart from each other in each of the first and second directions D1 and D2.

In example embodiments, the contact plug 470 may extend in the third direction D3 partially through one of the sixth stack structures 345 that is disposed between ones of the second and third sub conductive lines 350b and 350c neighboring in the first direction D1 and one of the sixth stack structures 345 that is disposed between ones of the third and first sub conductive lines 350c and 350a neighboring in the first direction D1. That is, the contact plug 470 may extend through ones of the sixth stack structures 345 that are not disposed at the (3n)-th positions.

Thus, the contact plugs 470 may extend through the sixth stack structures 345 disposed at opposite sides in the first direction D1 of each of the fourth conductive lines 410.

In example embodiments, the contact plug 470 may include a lower portion having a first width and an upper portion having a second width greater than the first width. The lower portion of the contact plug 470 may contact inner sidewalls in the first direction D1 and a lower portion of the third insulation pattern 330, a lower portion of the second insulation pattern 320, a sidewall of the second gate insulation layer structure 265 and an upper surface of the channel layer 240, and the upper portion of the contact plug 470 may contact an inner sidewall in the first direction D1 of the third insulation pattern 330, an upper surface of the third insulation pattern 330 and an upper surface of the second insulation pattern 320.

In example embodiments, the contact plugs 470 at opposite sides of the fourth conductive line 410 in the first direction D1 may have a symmetrical shape with reference to the fourth conductive line 410. For example, upper portions of the contact plugs 470 at opposite sides of the fourth conductive line 410 in the first direction D1 may protrude from the lower portions of the contact plugs 470 towards the fourth conductive line 410.

The contact plug 470 may include a conductive material, e.g., a metal, a metal nitride, a metal silicide, etc.

The ninth insulation layer 490 may be disposed on the third and fourth conductive lines 350 and 410, and may cover sidewalls and upper portions of the sixth stack structure 345 and the contact plug 470. The ninth insulation layer 490 may include an insulating nitride, e.g., silicon nitride.

The capacitor 530 may include a first capacitor electrode 500, a dielectric layer 510 and a second capacitor electrode 520 sequentially stacked. In example embodiments, the first capacitor electrode 500 may extend through an upper portion of the ninth insulation layer 490, and may contact an upper surface of the contact plug 470. Thus, a plurality of capacitors 530 may be spaced apart from each other in each of the first and second directions D1 and D2.

The plate electrode 540 may be disposed on the second capacitor electrodes 530, and may fill a space between the second capacitor electrodes 530.

FIGS. 1 to 5 show that the first capacitor electrode 500 has a shape of a pillar extending in the third direction D3, however, inventive concepts may not be limited thereto, and the first capacitor electrode 500 may have, for example, a shape of a cup or a hollow cylinder.

Each of the first and second capacitor electrodes 500 and 520 may include a conductive material, e.g., a metal, a metal nitride, a metal silicide, etc., and the plate electrode 540 may include, e.g., silicon-germanium undoped or doped with p-type impurities.

The dielectric layer 510 may include a paraelectric material or a ferroelectric material. In an example embodiment, the dielectric layer 510 may include a metal oxide having a high dielectric constant, e.g., hafnium oxide, zirconium oxide, etc. In another example embodiment, the dielectric layer 510 may include hafnium oxide, zirconium oxide, etc., doped with, e.g., silicon, zirconium, aluminum, yttrium, lanthanum, carbon, nitrogen, germanium, tin, strontium, lead, calcium, barium, titanium, tantalum, gadolinium, etc.

The semiconductor device may include the word lines 180 and the first conductive division lines 120 each of which may extend in the first direction D1, the bit lines 410, the first and second sub conductive lines 350a and 350b and the second conductive line 350c each of which may extend in the second direction D2, and the channel layer 240 on an entire portion of the substrate 100.

A portion of the channel layer 240 (referred to as a channel) at an area where the word line 180 and the bit line 410 cross each other, the second gate electrode included in a portion of the word line 180 adjacent to the channel, and a portion of the second gate insulation layer structure 265 adjacent to the second gate electrode may collectively form a cell transistor, and the cell transistor and the capacitor 530 electrically connected to the cell transistor may form a memory cell (indicated by region X in FIGS. 2 to 4). In example embodiments, a plurality of memory cells may be spaced apart from each other in each of the first and second directions D1 and D2 to form a memory cell array.

In example embodiments, the channel layer 240 may be disposed on the entire portion of the substrate 100, instead of being divided into a plurality of parts in the first direction D1 or in the second direction D2. However, the semiconductor device may include the first and second conductive division lines 120 and 350c, and as illustrated below, portions of the channel layer 240 included in ones of the memory cells disposed in the second direction D2 may be electrically separated from each other by the first conductive division line 120, and portions of the channel layer 240 included in ones of the memory cells disposed in the first direction D1 may be electrically separated from each other by the second conductive division line 350c.

As illustrated, each of the first and second sub conductive lines 350a and 350b may serve as a select line for selecting some of the memory cells disposed in the second direction D2, and thus the first and second sub conductive lines 350a and 350b may also be referred to as first and second select lines 350a and 350b, respectively.

As illustrated, the channel layer 240 may be disposed on the entire portion of the substrate 100 and may not be divided into a plurality of parts, so that an etching process for dividing the channel layer 240 into a plurality channels is not needed and that the channel layer 240 may not be damaged by the etching process. Accordingly, the memory cells including the channel layer 240 and the semiconductor device including the same may have enhanced electrical characteristics.

FIG. 6 is a circuit diagram illustrating a memory cell included in the semiconductor device, and FIG. 7 is a graph illustrating an operation of read for the memory cell.

Referring to FIGS. 6 and 7 together with FIGS. 1 to 5, a negative voltage may be applied to each of the first and second conductive division lines 120 and 350c so that each of the first and second conductive division lines 120 and 350c may maintain an off-state, and the channel layer 240 may include an oxide semiconductor material having a low leakage current, so that portions of the channel layer 240 included in the memory cells, respectively, may be electrically divided into a plurality of channels that may be electrically insulated from each other by the first and second conductive division lines 120 and 350c, even though the channel layer 240 is not physically divided into a plurality of channels.

That is, the portions of the channel layer 240 included in the memory cells, respectively, disposed in the second direction D2 may be electrically insulated from each other because the first conductive division line 120 is always in an off-state, and the portions of the channel layer 240 included in the memory cells, respectively, disposed in the first direction D1 may be electrically insulated from each other because the second conductive division line 350c is always in an off-state. Thus, the channel layer 240 may be divided into channels that are electrically insulated from each other in each of the first and second directions D1 and D2 by the first and second conductive division lines 120 and 350c, which may form a channel array.

When a positive voltage is applied to the bit line 410 and the word line 180, if the second select line 350b is in an off-state and a positive voltage is applied to the first select line 350a, an operation of read for a first memory cell connected to the first select line 350a may be performed. When a positive voltage is applied to the bit line 410 and the word line 180, if the first select line 350a is in an off-state and a positive voltage is applied to the second select line 350b, an operation of read for a second memory cell connected to the second select line 350b may be performed.

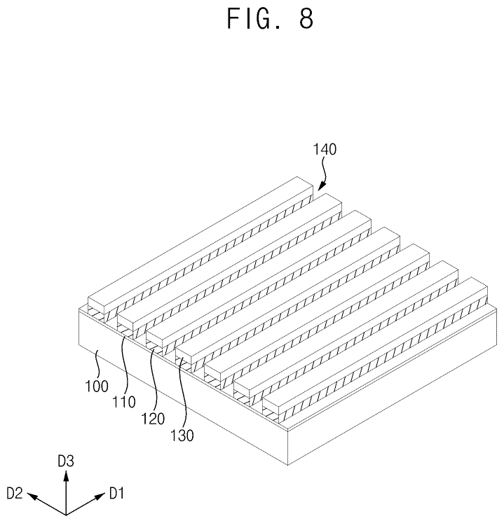

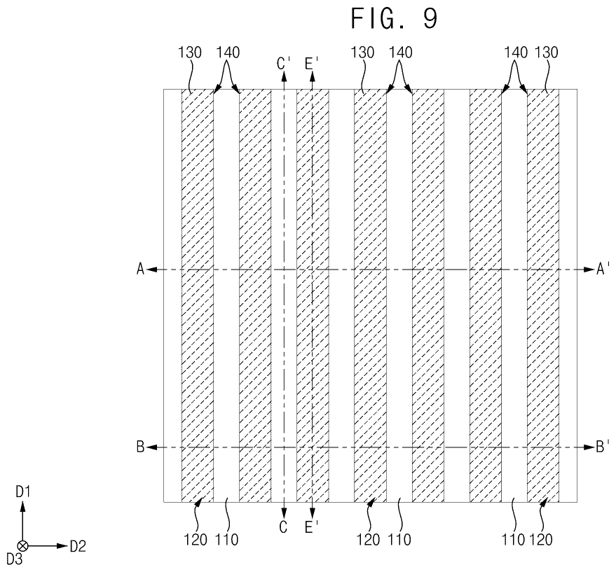

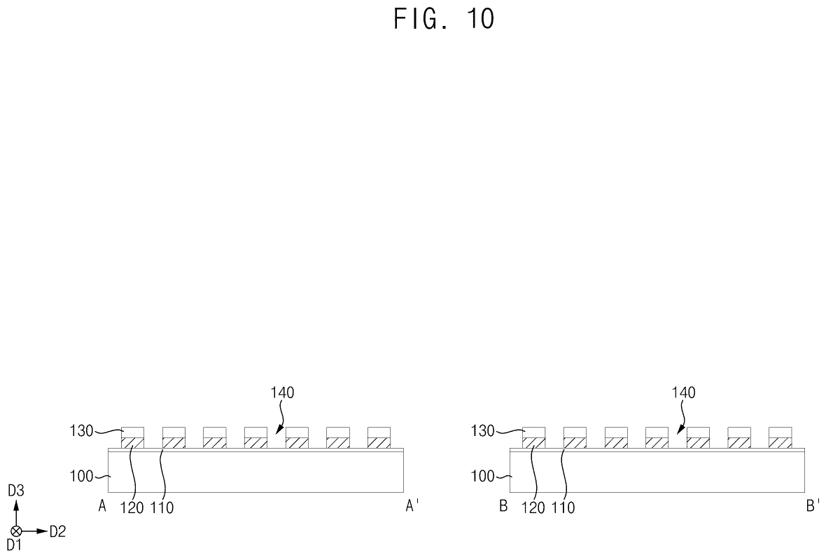

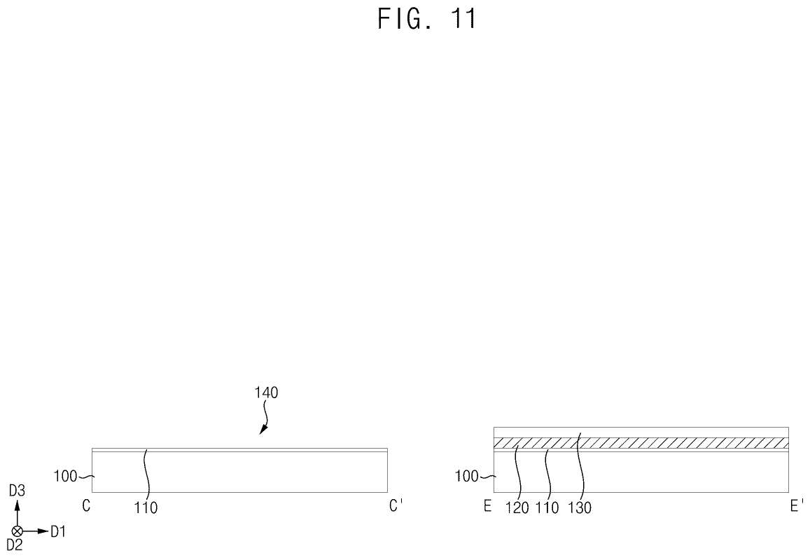

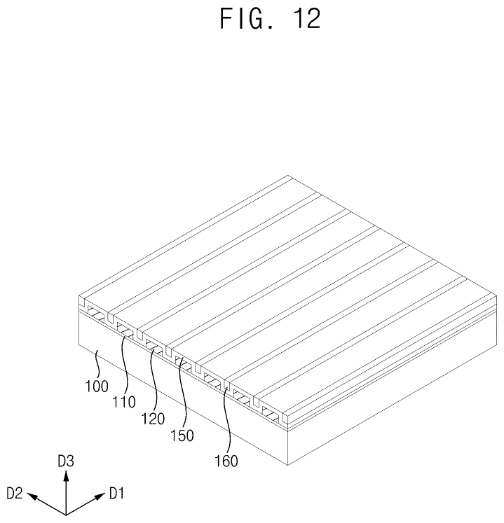

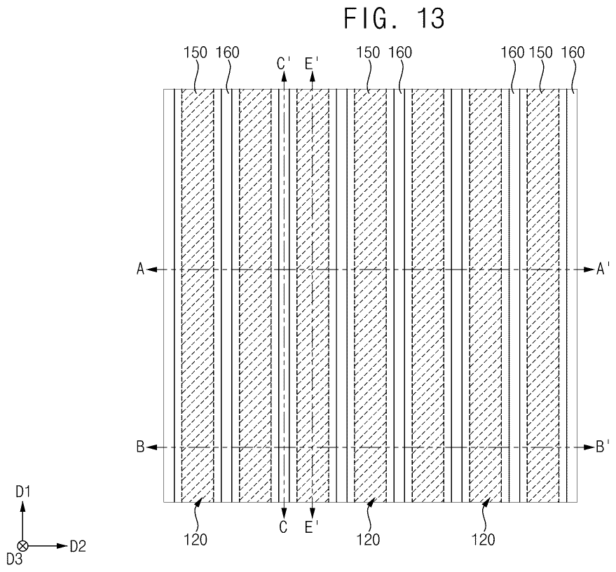

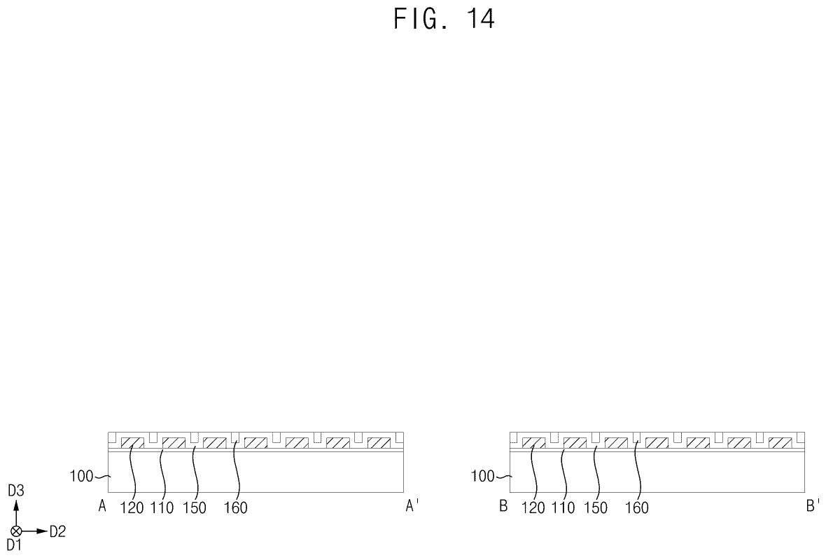

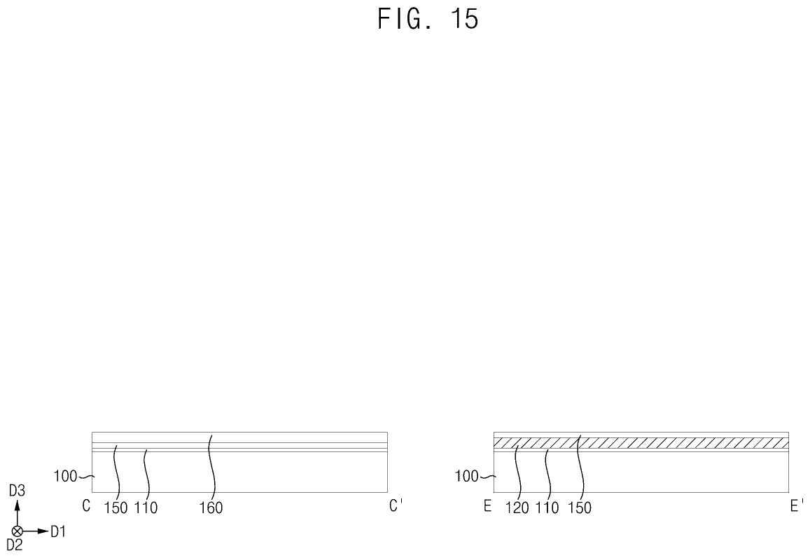

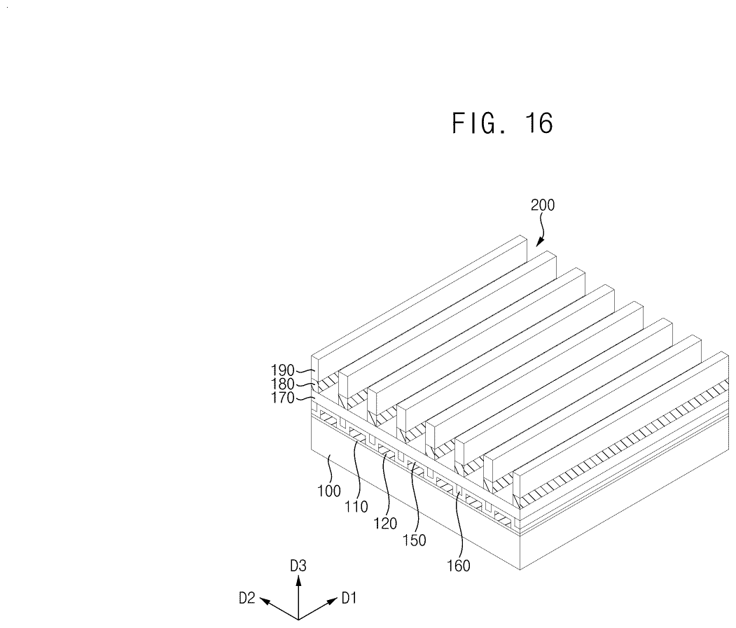

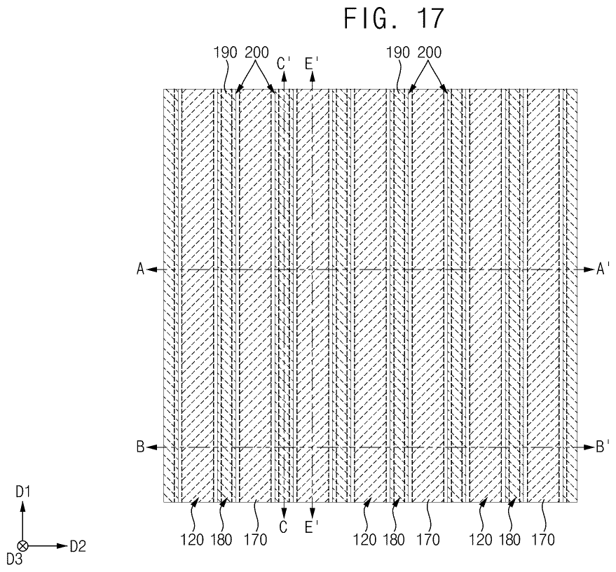

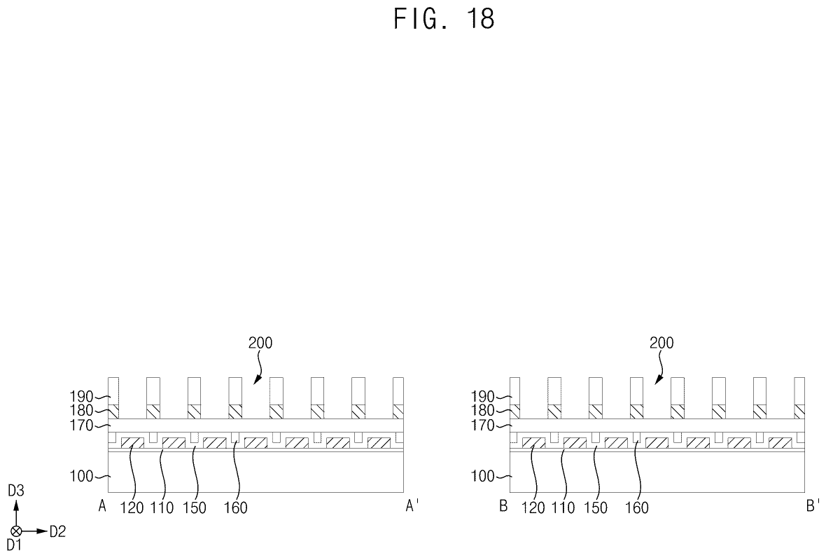

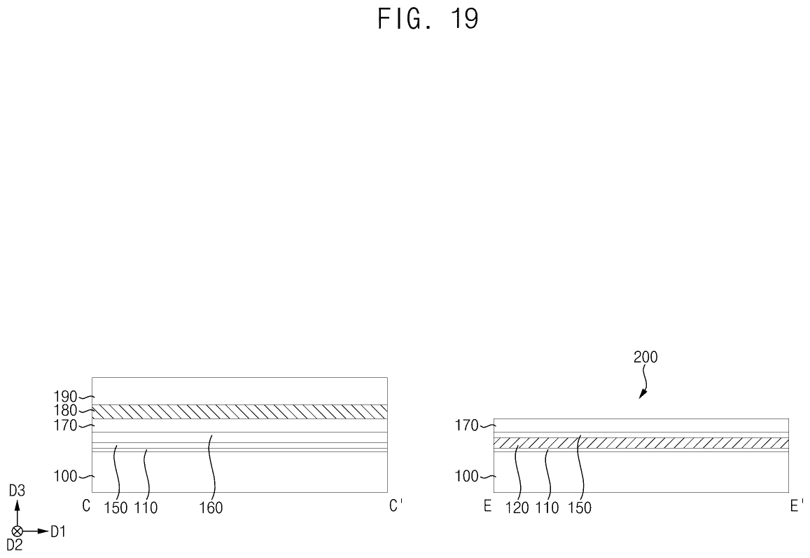

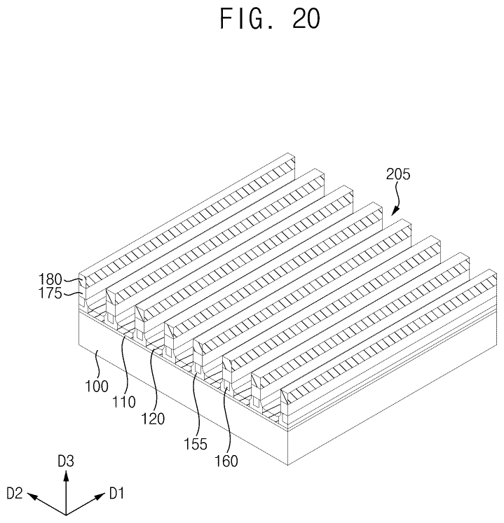

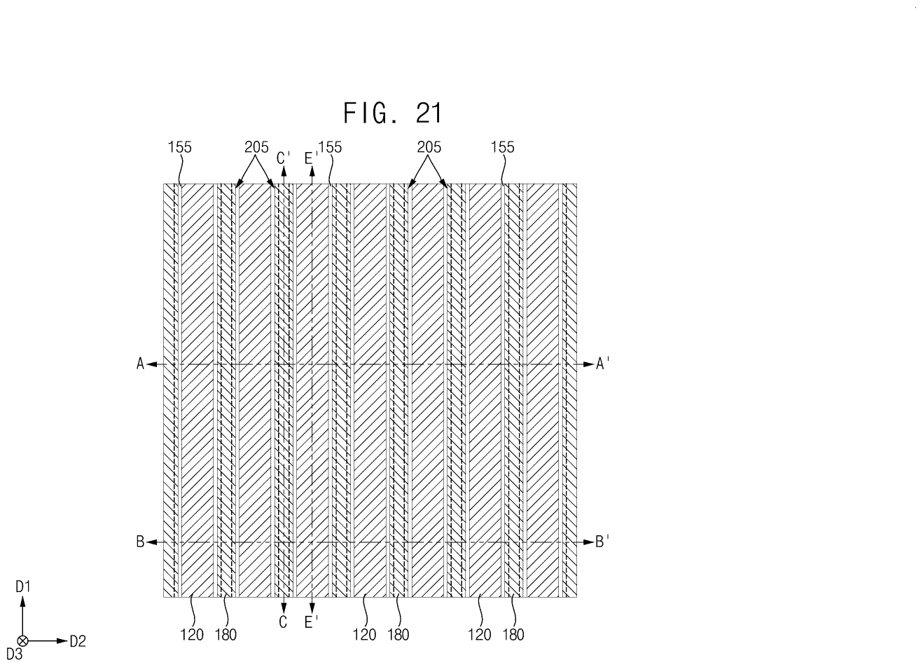

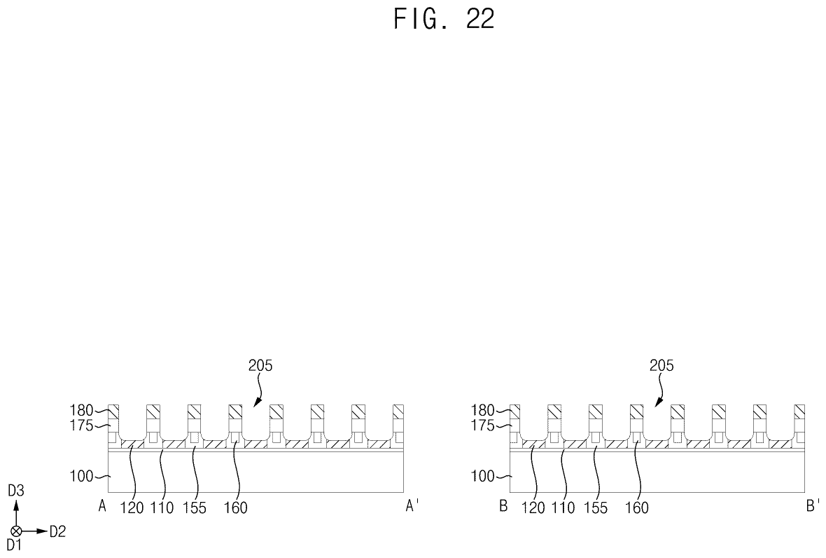

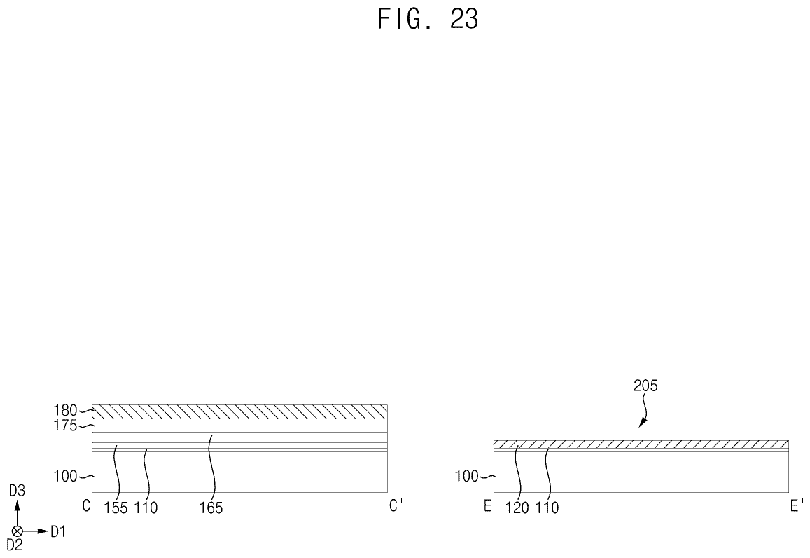

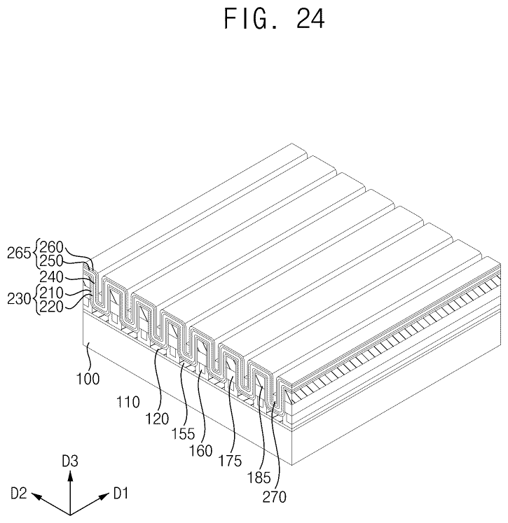

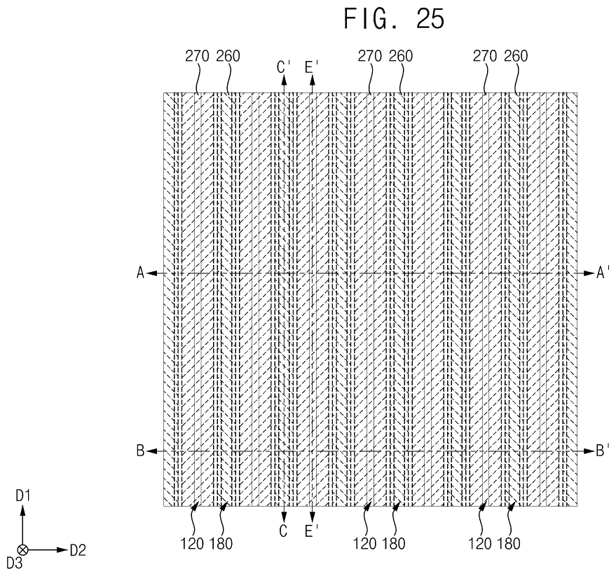

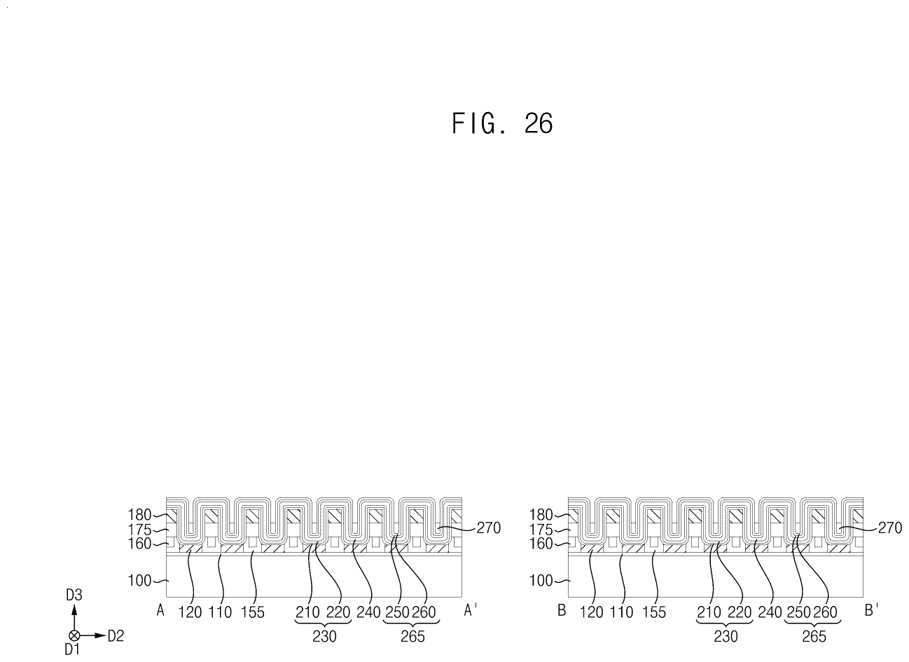

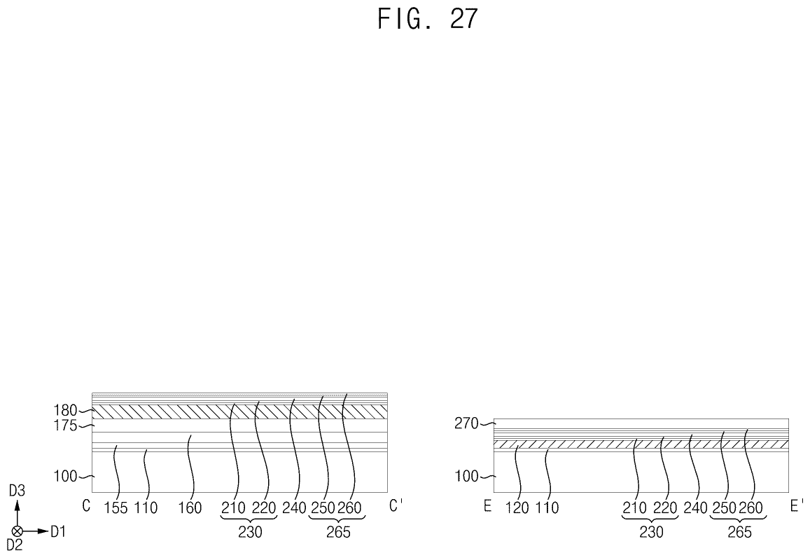

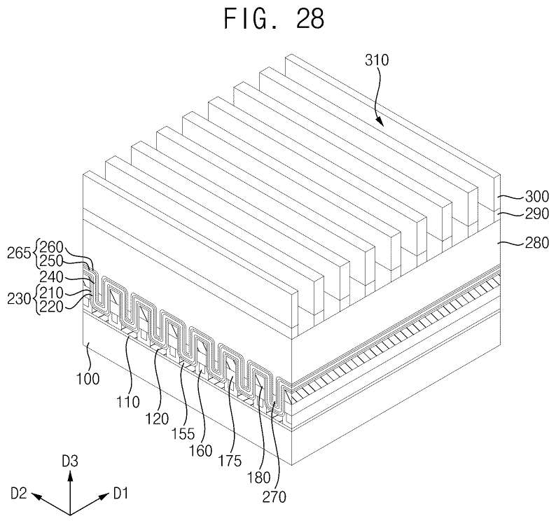

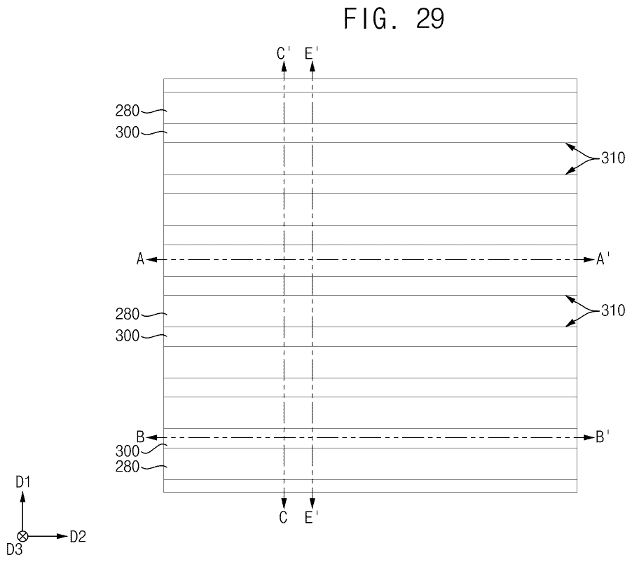

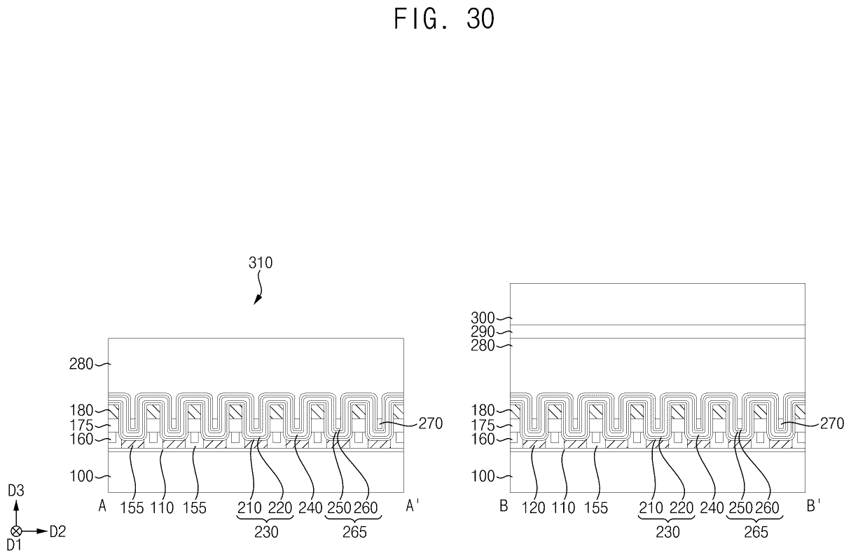

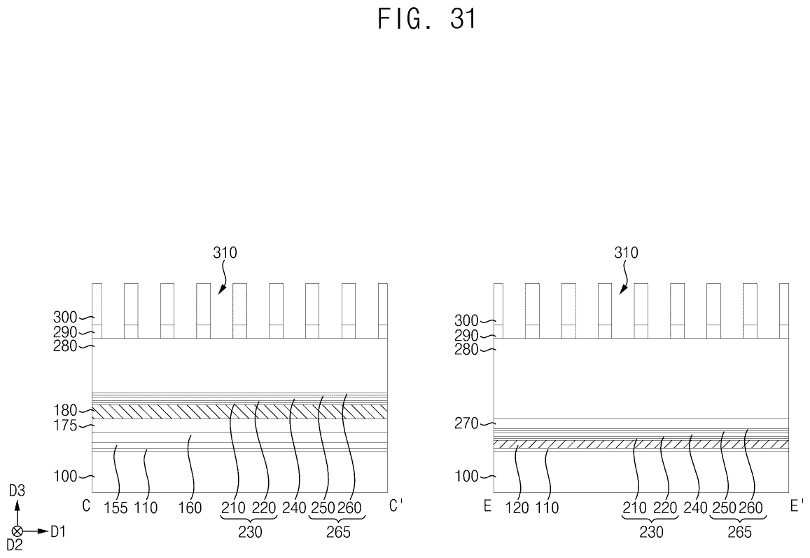

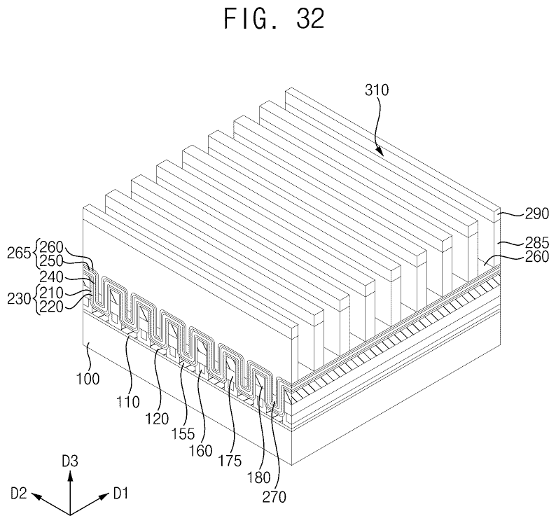

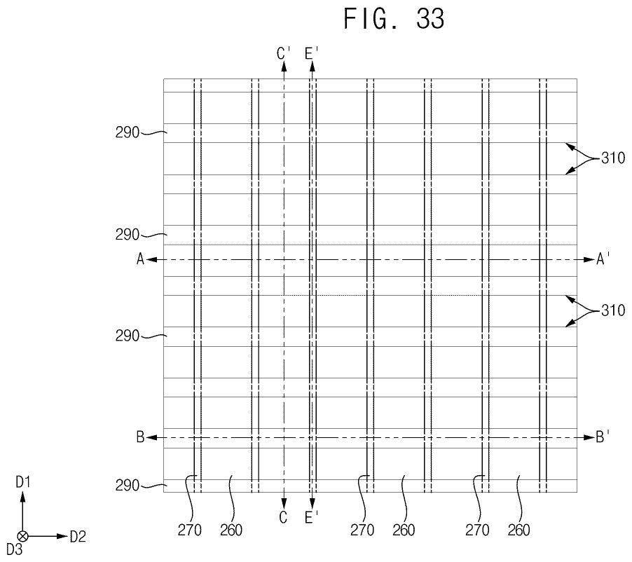

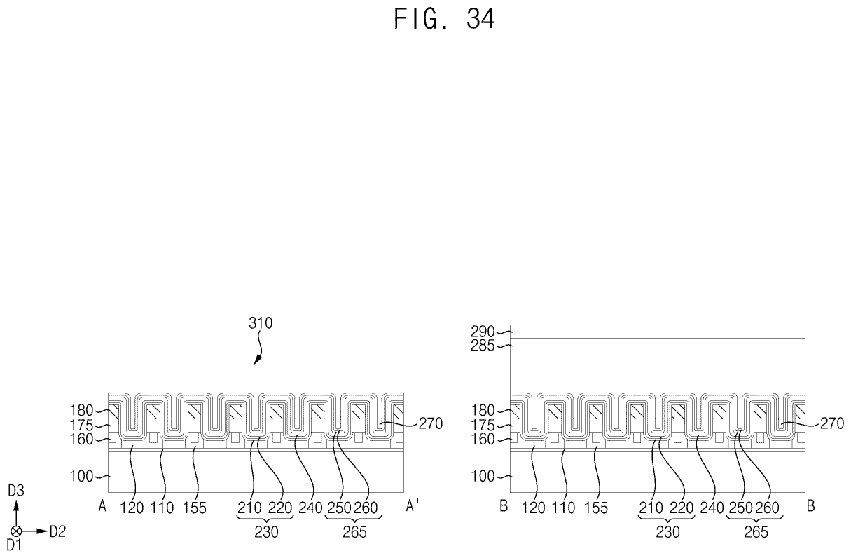

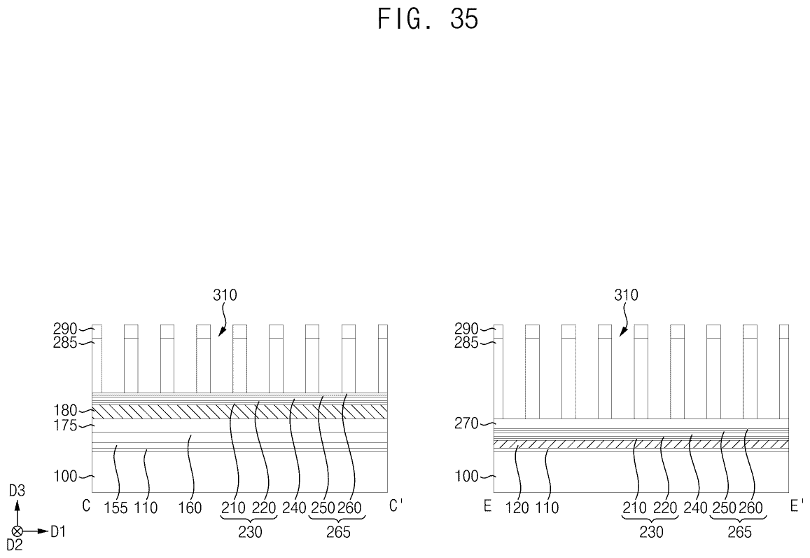

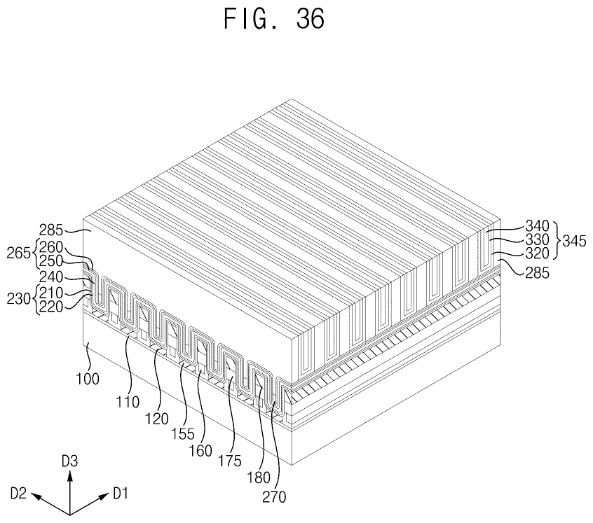

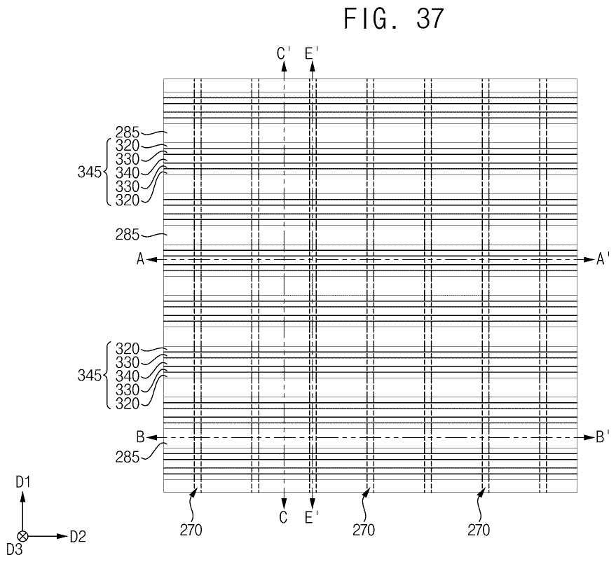

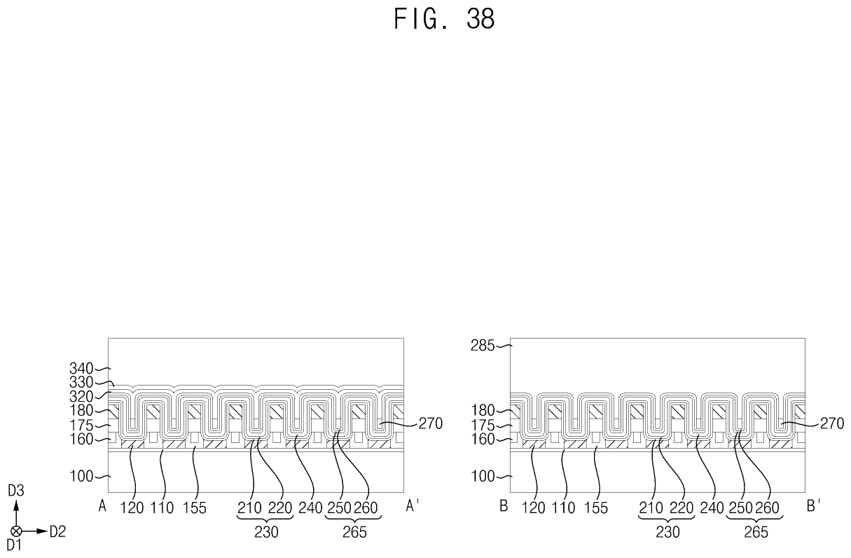

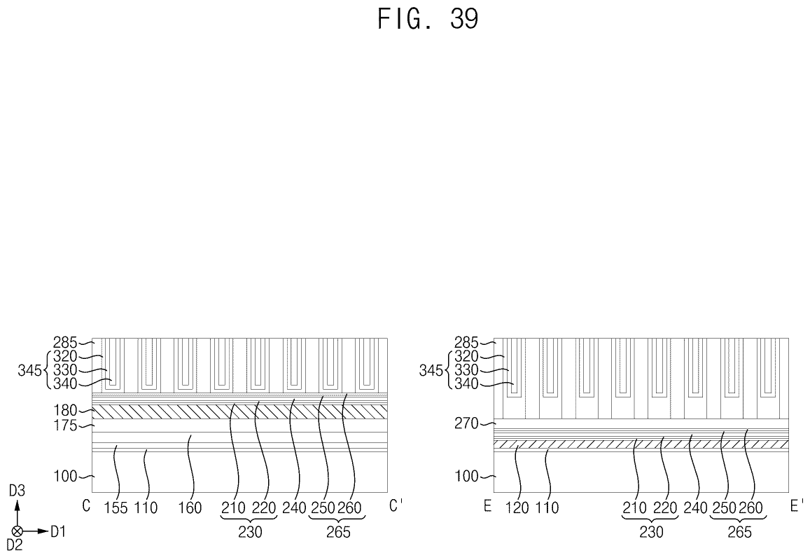

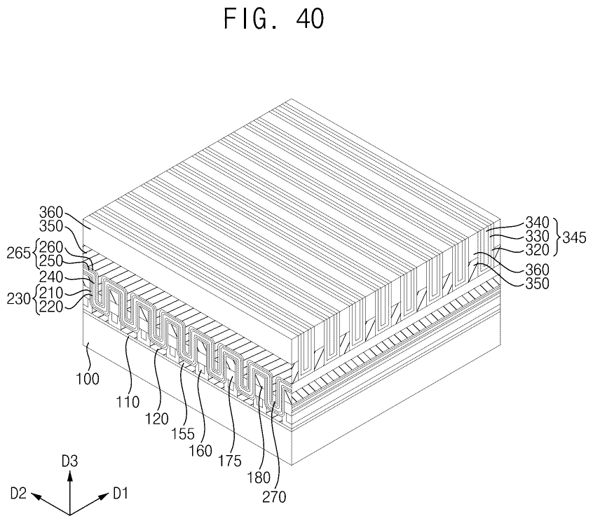

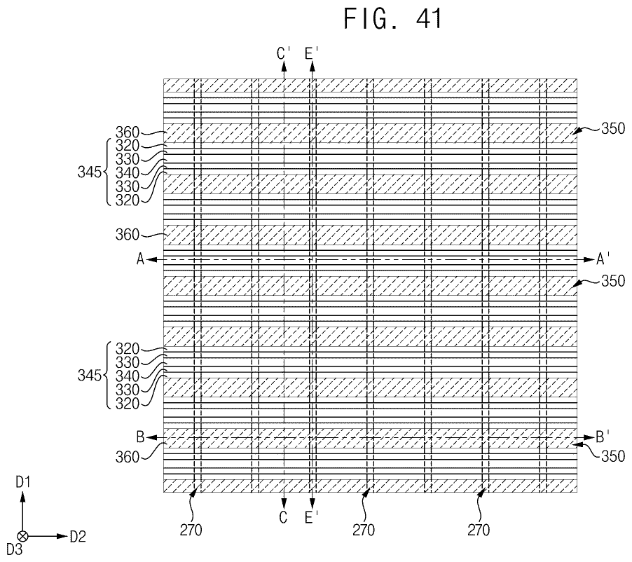

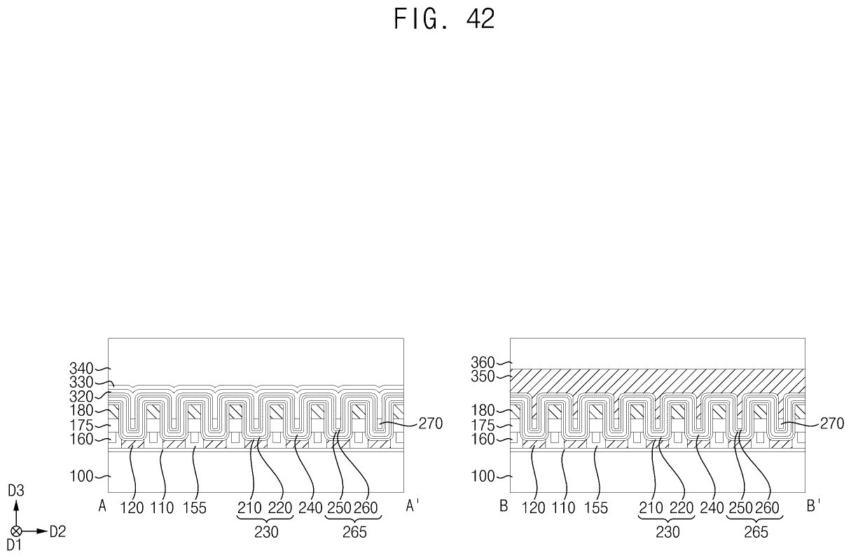

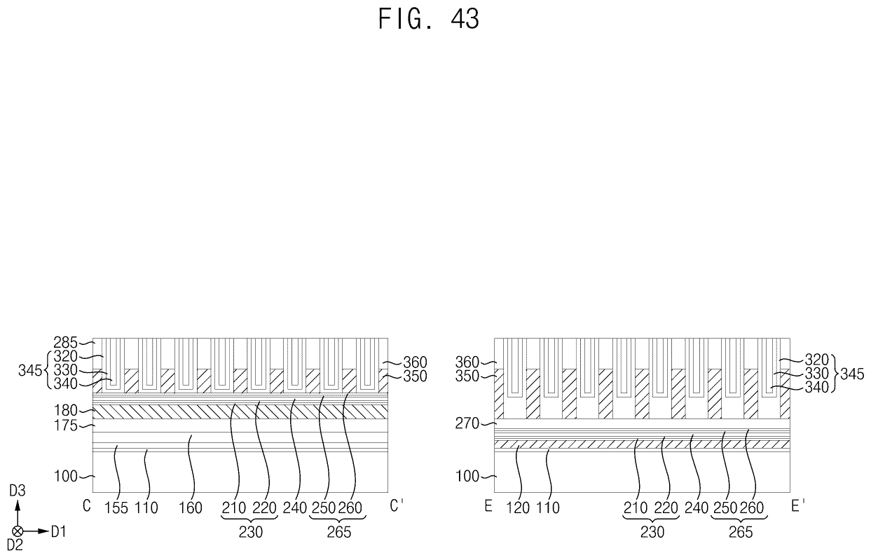

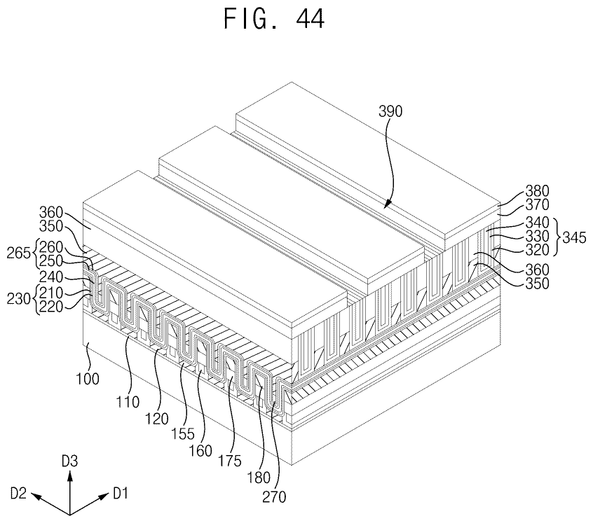

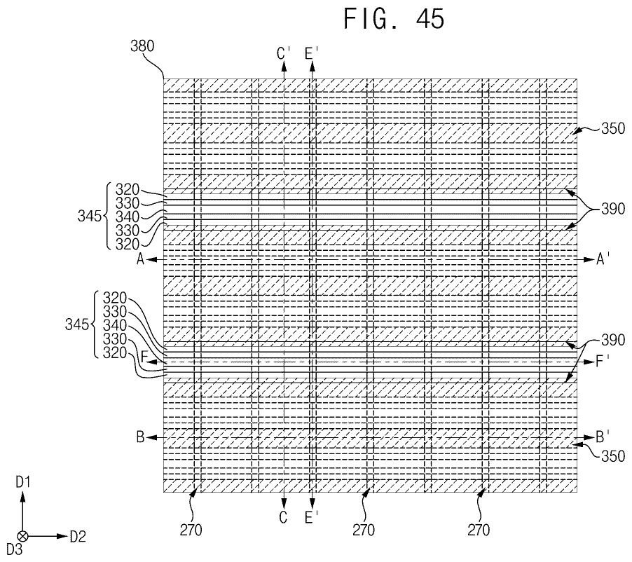

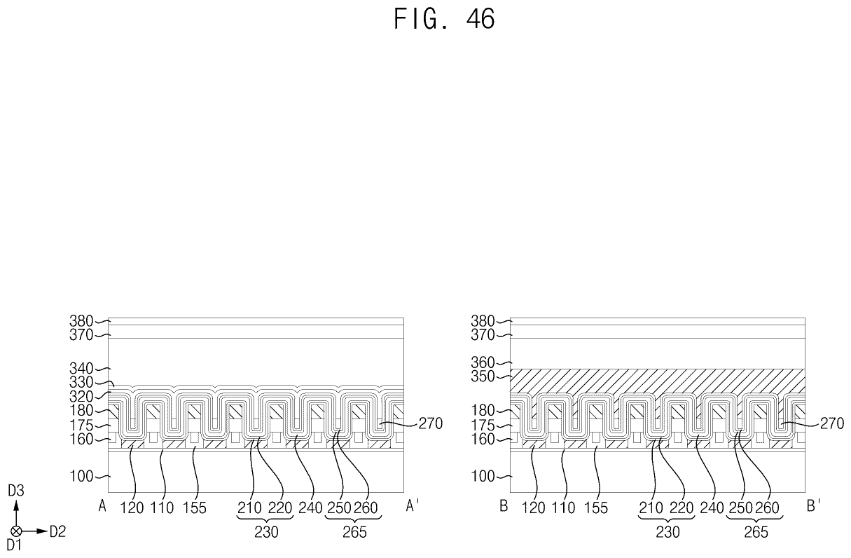

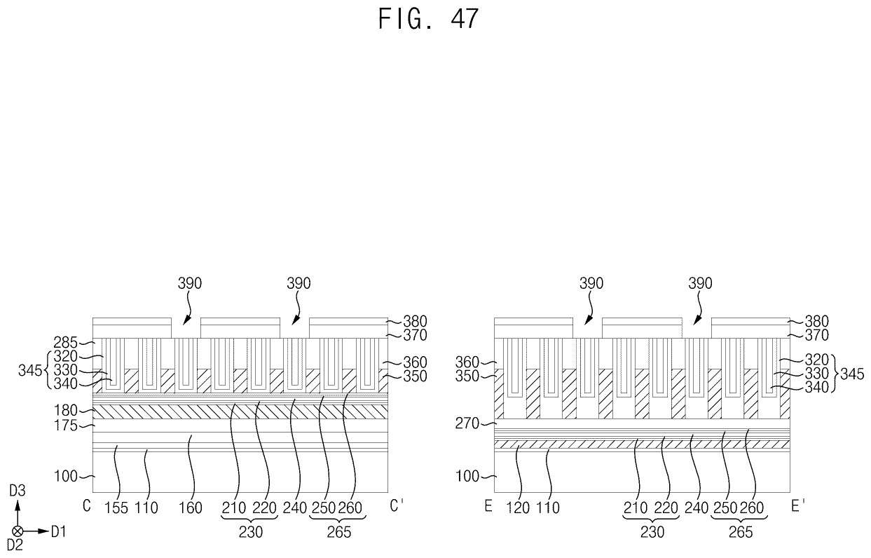

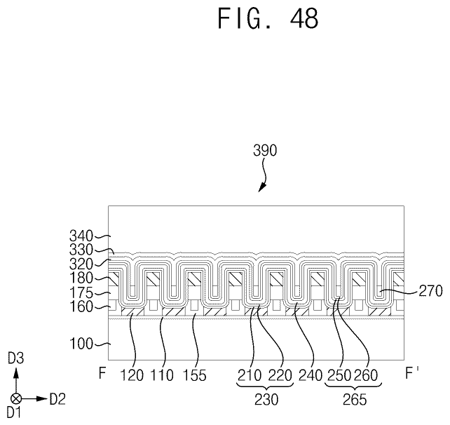

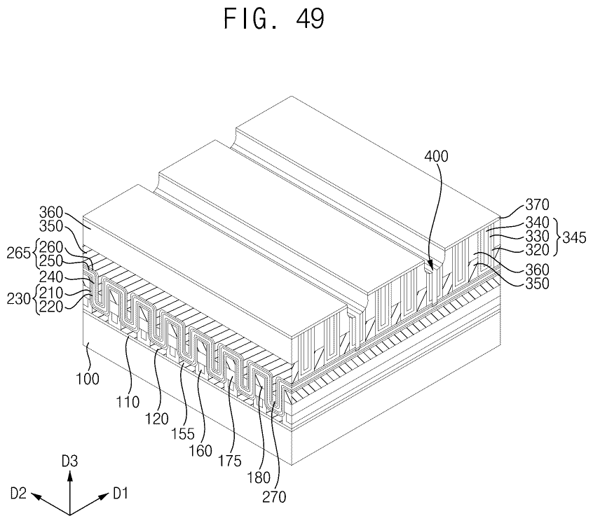

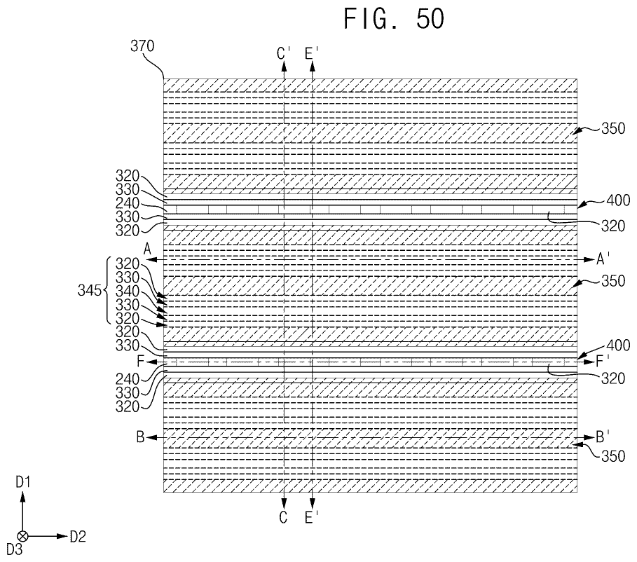

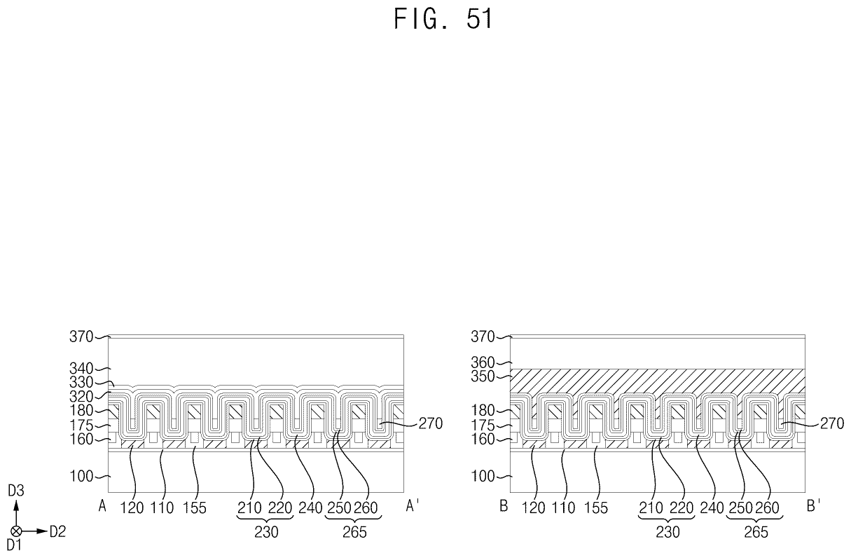

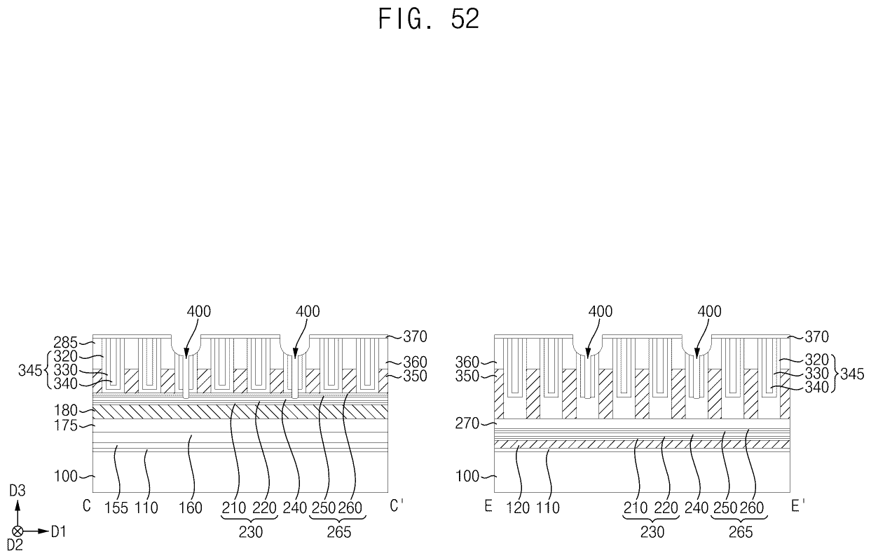

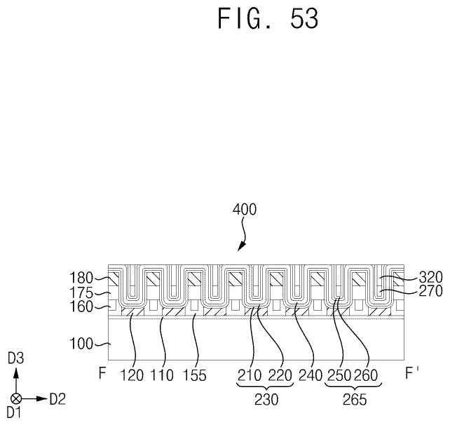

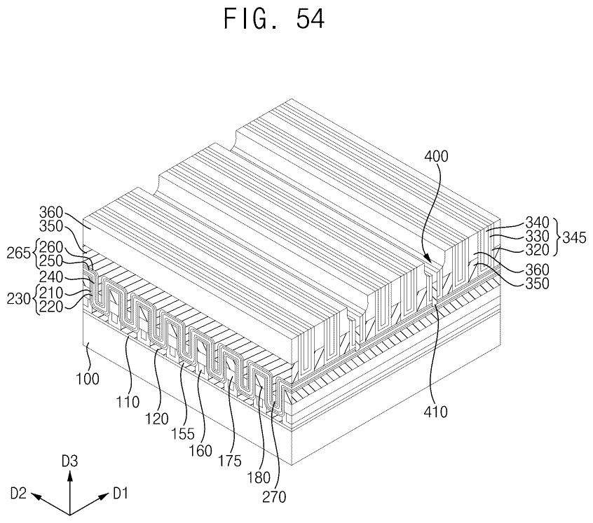

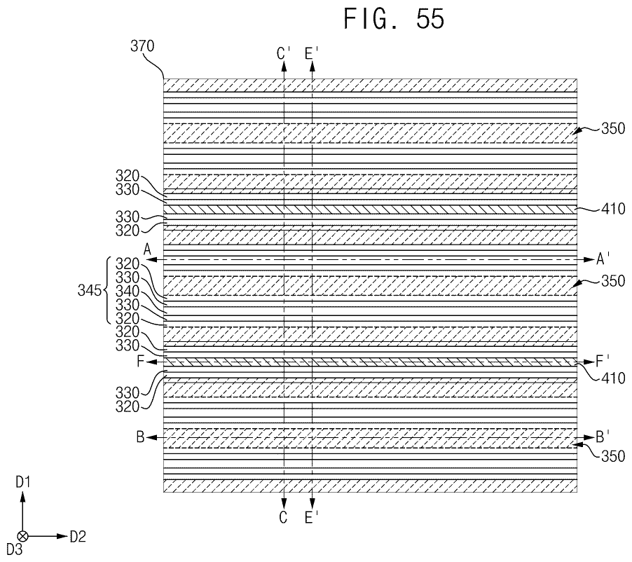

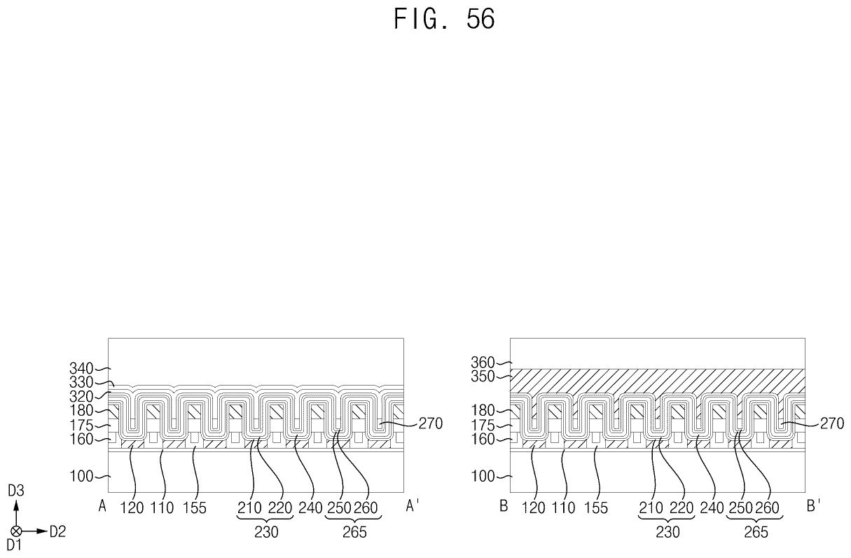

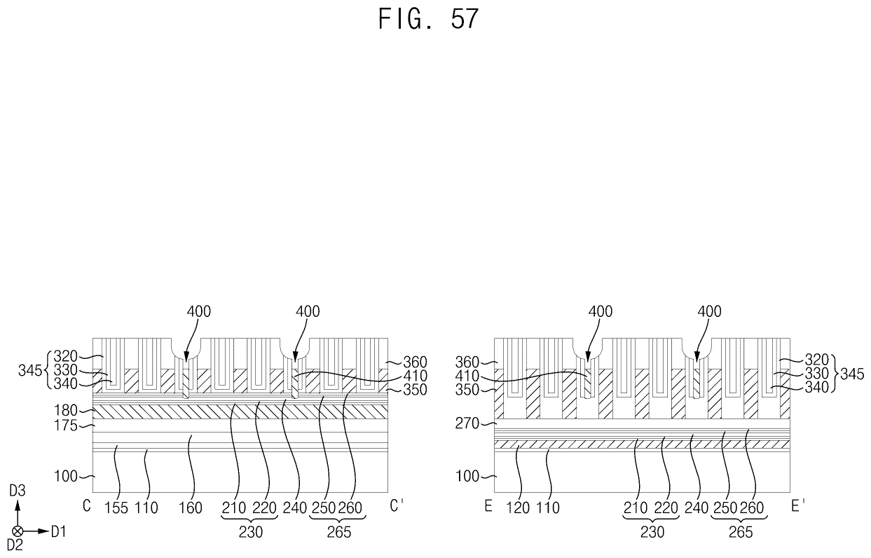

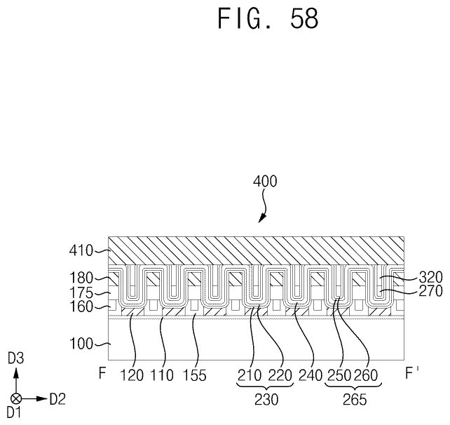

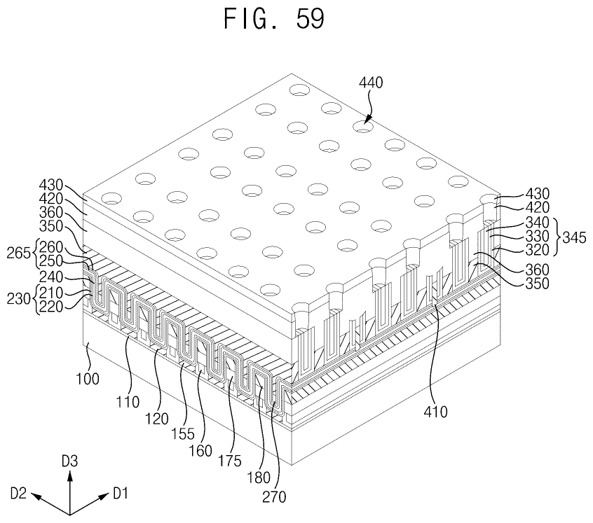

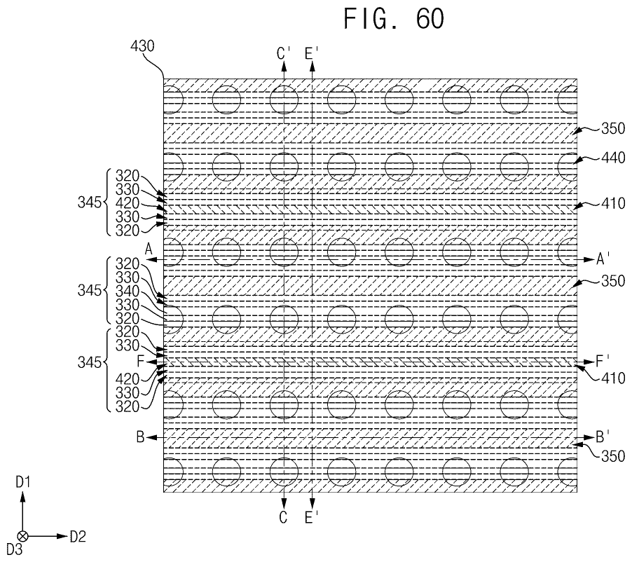

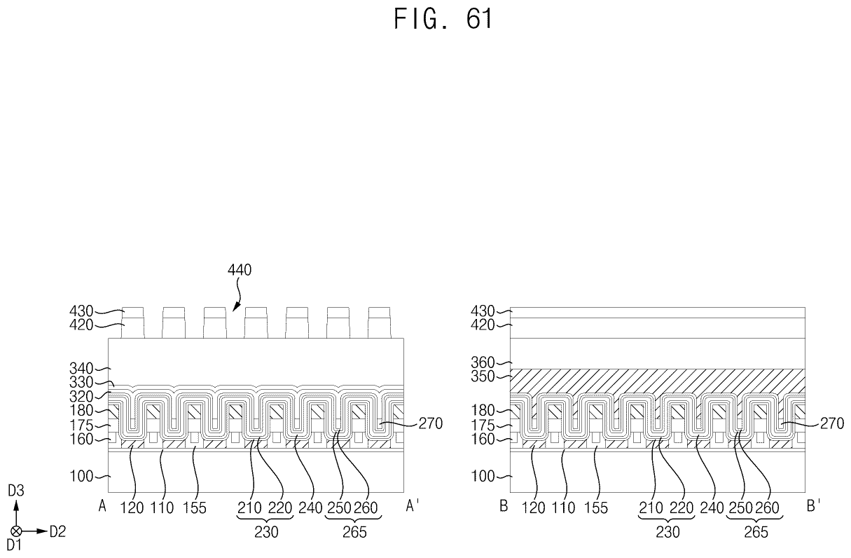

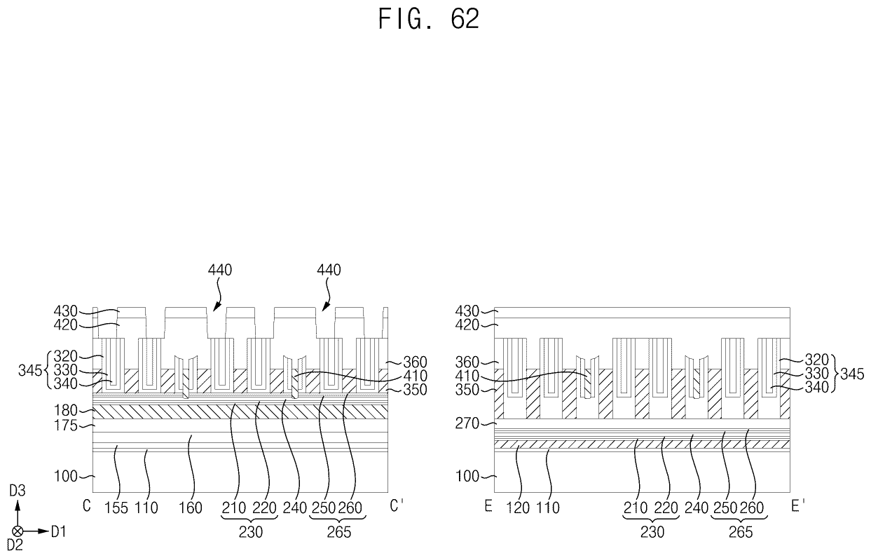

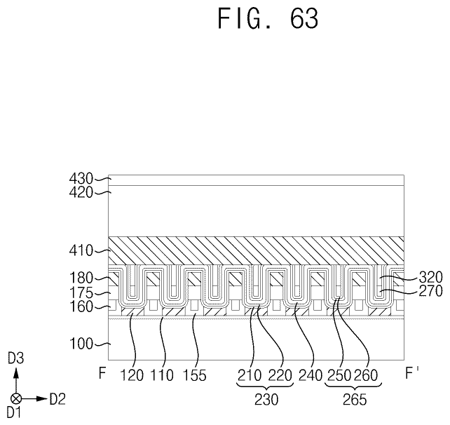

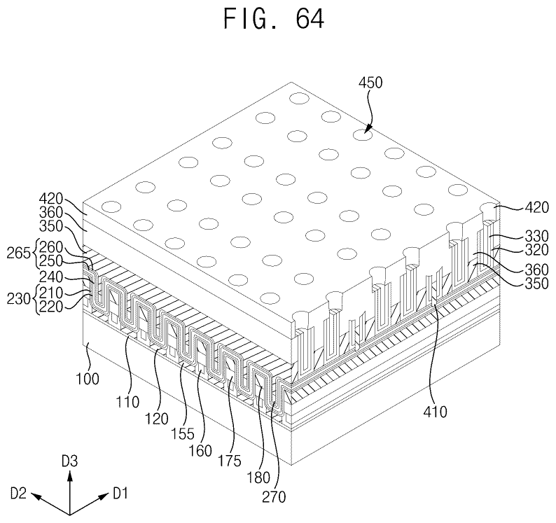

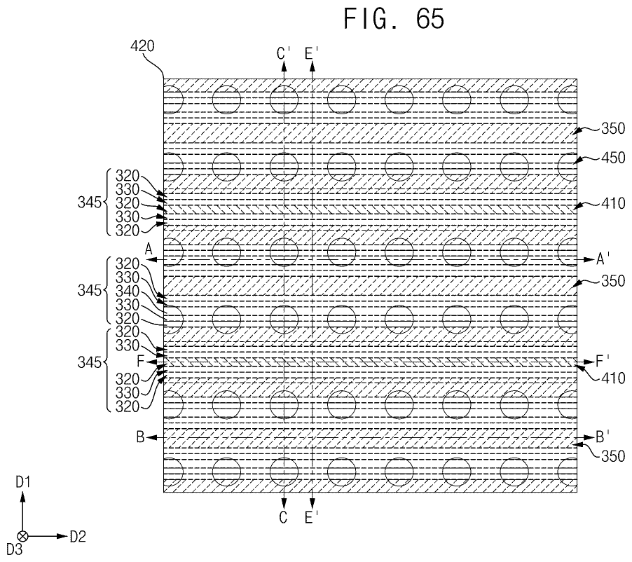

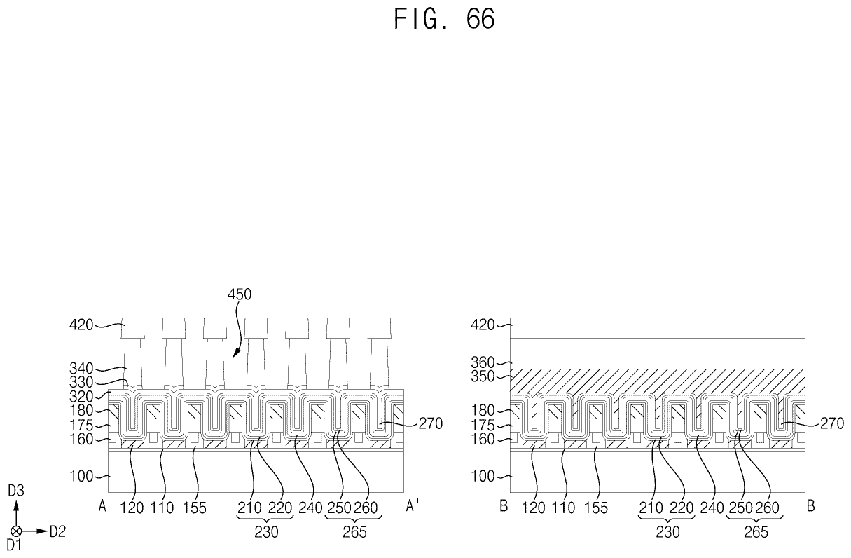

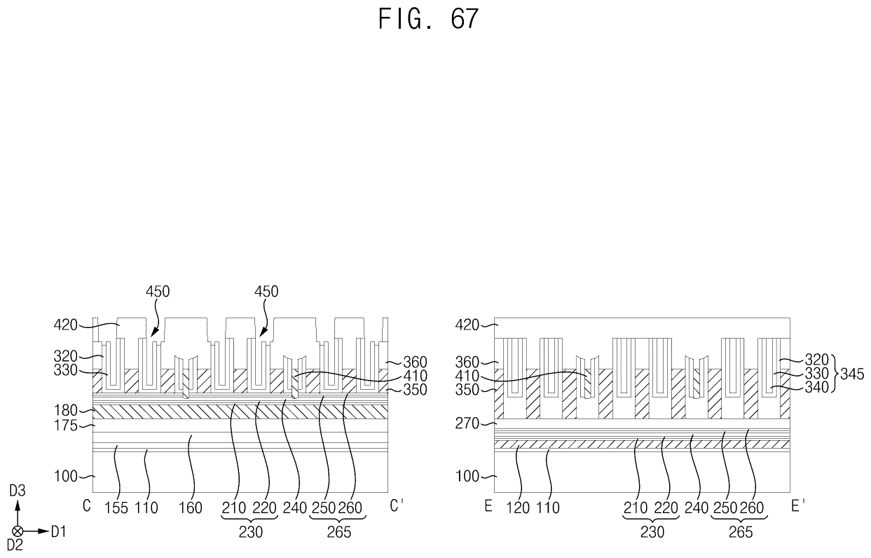

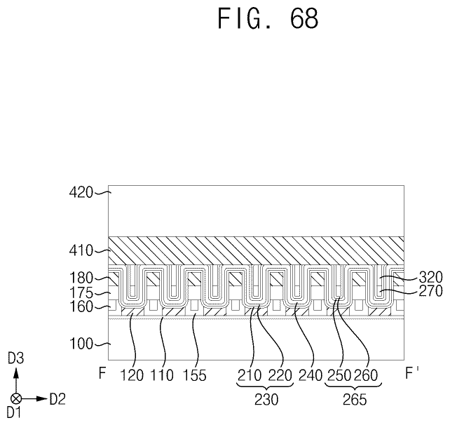

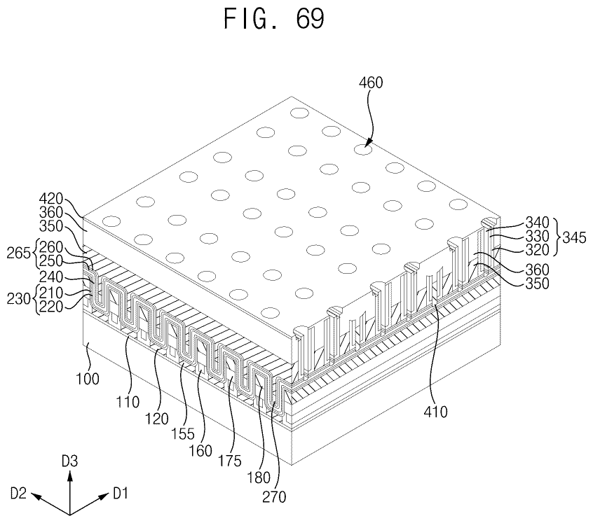

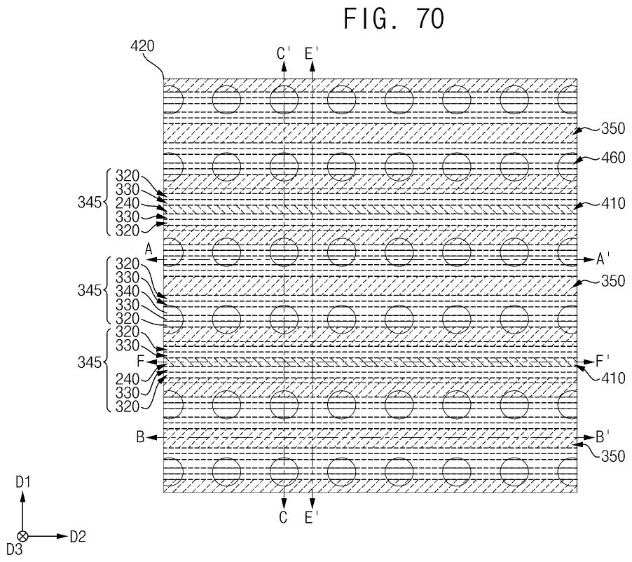

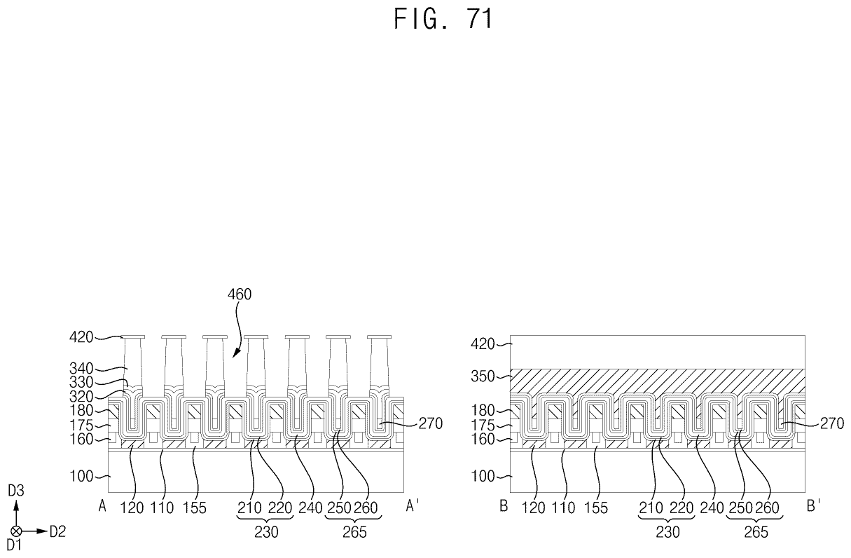

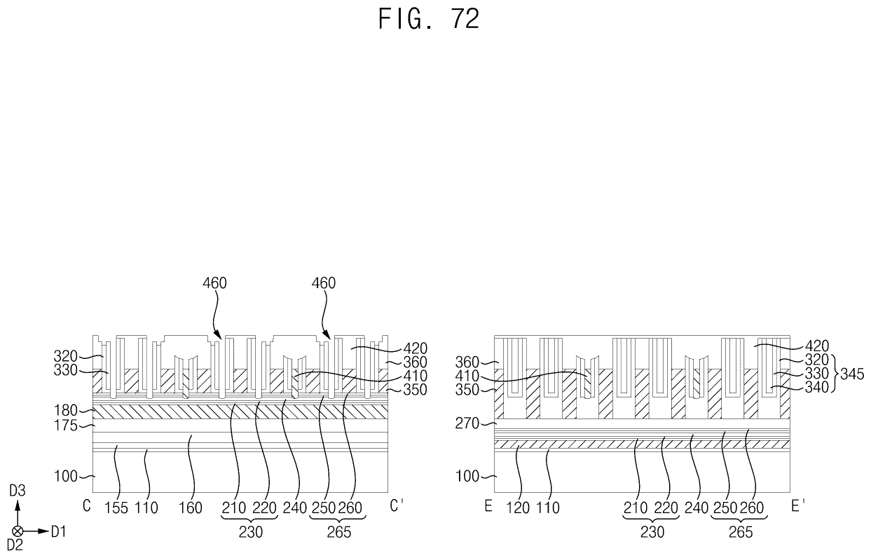

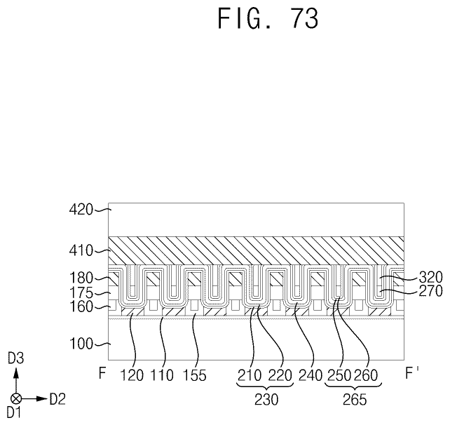

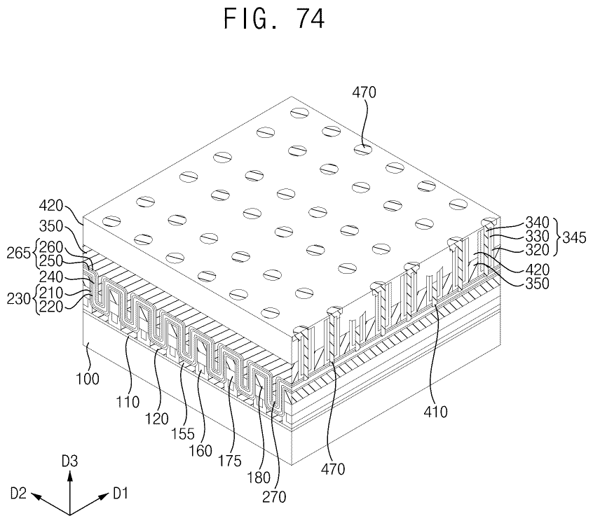

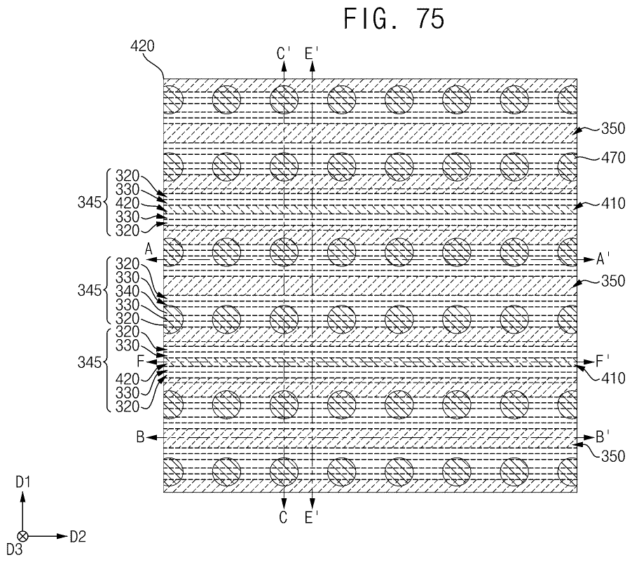

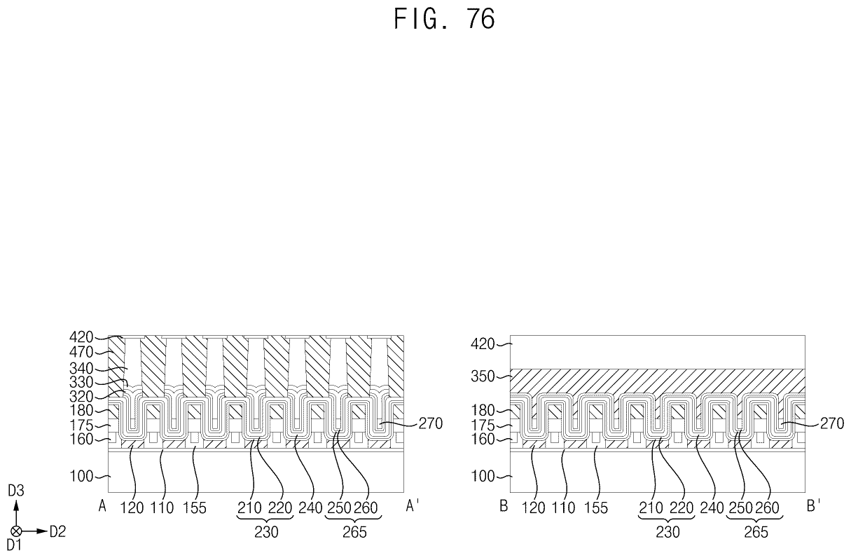

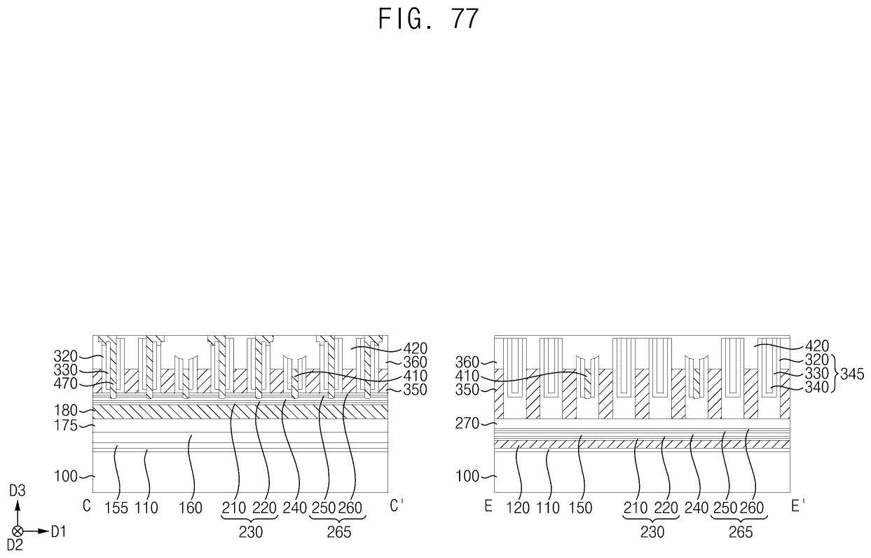

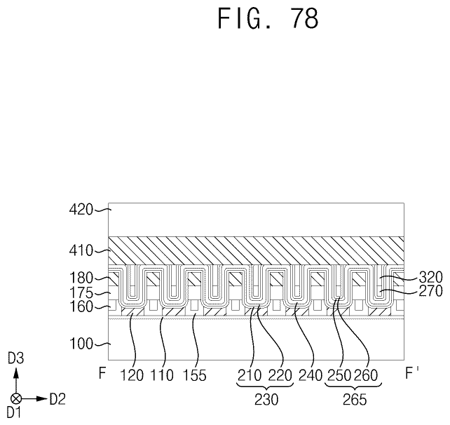

FIGS. 8 to 78 are perspective views, plan views and cross-sectional views illustrating a method of manufacturing a semiconductor device in accordance with example embodiments.

Specifically, FIGS. 8, 12, 16, 20, 24, 28, 32, 36, 40, 44, 49, 54, 59, 64, 69 and 74 are the perspective views, FIGS. 9, 13, 17, 21, 25, 29, 33, 37, 41, 45, 50, 55, 60, 65 and 70 are the plan views, each of FIGS. 10, 14, 18, 22, 26, 30, 34, 38, 42, 46, 51, 56, 61, 66 and 71 includes cross-sectional views taken along lines A-A′ and B-B′, respectively, of a corresponding plan view, each of FIGS. 11, 15, 19, 23, 27, 31, 35, 39, 43, 47, 52, 57, 62, 67 and 72 includes cross-sectional views taken along lines C-C′ and E-E′, respectively, of a corresponding plan view, and FIGS. 48, 53, 58, 63, 68, 73 and 78 are cross-sectional views taken along lines F-F′ of corresponding plan views, respectively.

Referring to FIGS. 8 to 11, a pad layer 110 and a first conductive layer may be sequentially stacked in the third direction D3 on a substrate 100, a planarization process, e.g., a chemical mechanical polishing (CMP) process may be performed on the first conductive layer, a first mask layer may be formed on the first conductive layer, the first mask layer may be patterned to form first masks 130, each of which may extend in the first direction D1, spaced apart from each other in the second direction D2, and the first conductive layer may be patterned using the first masks 130 as an etching mask to form first conductive lines 120, each of which may extend in the first direction D1, spaced apart from each other in the second direction D2.

By the etching process, a first opening 140 may be formed between first stack structures, each of which may include the first conductive line 120 and the first mask 130 stacked in the third direction D3, to extend in the first direction D1 and expose an upper surface of the pad layer 110.

The first mask 130 may include, e.g., a photoresist pattern.

Lower circuit patterns and a lower insulating interlayer covering the lower circuit patterns may be further formed on the substrate 100, and in this case, the pad layer 110 may be formed on the lower insulating interlayer.

Referring to FIGS. 12 to 15, the first mask 130 may be removed by, e.g., an ashing process and/or a stripping process, a first capping layer 150 may be conformally formed on the pad layer 110 to cover the first conductive line 120, an insulating interlayer may be formed on the first capping layer 150 to fill the first opening 140, and a planarization process may be performed on the insulating interlayer until an upper surface of the first capping layer 150 is exposed to form insulating interlayer patterns 160, each of which may extend in the first direction D1, spaced apart from each other in the second direction D2.

Thus, a sidewall and a lower surface of each of the insulating interlayer patterns 160 may be covered by the first capping layer 150.

Referring to FIGS. 16 to 19, a first mold layer 170 may be formed on the first capping layer 150 and the insulating interlayer patterns 160, a second conductive layer may be formed on the first mold layer 170, and a planarization process, e.g., a CMP process may be performed on the second conductive layer, a second mask layer may be formed on the second conductive layer, the second mask layer may be patterned to form second masks 190, each of which may extend in the first direction D1, spaced apart from each other in the second direction D2, and an etching process may be performed on the second conductive layer using the second masks 190 as an etching mask to form second conductive lines 180, each of which may extend in the first direction D1, spaced apart from each other in the second direction D2.

In example embodiments, each of the second conductive lines 180 may overlap in the first direction D1 the insulating interlayer pattern 160 and portions of the first capping layer 150 at respective opposite sides in the second direction D2 of the insulating interlayer pattern 160.

By the etching process, a second opening 200 may be formed between second stack structures, each of which may include the second conductive line 180 and the second mask 190 stacked in the third direction D3, to extend in the first direction D1 and expose an upper surface of the first mold layer 170.

The second mask 190 may include, e.g., a photoresist pattern.

Referring to FIGS. 20 to 23, an etching process may be performed on the first mold layer 170 and the first capping layer 150 using the second stack structure as an etching mask.

Thus, the first mold layer 170 may be divided into a plurality of first molds 175, each of which may extend in the first direction D1, spaced apart from each other in the second direction D2. Additionally, a portion of the first capping layer 150 on an upper surface of the first conductive line 120 may also be removed to expose an upper surface of the first conductive line 120, and the first capping layer 150 may be divided into a plurality of first capping patterns 155, each of which may extend in the first direction D1 and cover a sidewall and a lower surface of the insulating interlayer pattern 160.

The second mask 190 may be removed by, e.g., an ashing process and/or a stripping process.

By the etching process, a third opening 205 may be formed between third stack structures, each of which may include the first mold 175 and the second conductive line 180 stacked in the third direction D3, to extend in the first direction D1 and expose the upper surface of the first conductive line 120 and a portion of an upper surface of the first capping pattern 155.

Referring to FIGS. 24 to 27, first and second gate insulation layers 210 and 220, a channel layer 240 and third and fourth gate insulation layers 250 and 260 may be sequentially stacked on the first conductive line 120 and the first capping pattern 155 to cover the third stack structure, a first insulation layer may be formed on the fourth gate insulation layer 260 to fill the third opening 205, and an upper portion of the first insulation layer may be removed by, e.g., an etch back process to form a first insulation pattern 270 extending in the first direction D1 and filling a lower portion of the third opening 205.

The first and second gate insulation layers 210 and 220 may collectively form a first gate insulation layer structure 230, and the third and fourth gate insulation layers 250 and 260 may collectively form a second gate insulation layer 265.

Referring to FIGS. 28 to 31, a sacrificial layer 280 may be formed on the fourth gate insulation layer 260 and the first insulation pattern 270, a planarization process such as a CMP process may be performed on the sacrificial layer 280, third and fourth mask layers may be sequentially stacked on the sacrificial layer 280, and the fourth mask layer may be patterned to form a plurality of fourth masks 300, each of which may extend in the second direction D2, spaced apart from each other in the first direction D1.

An etching process may be performed on the third mask layer using the fourth masks 300 as an etching mask to form a plurality of third masks 290, each of which may extend in the second direction D2, spaced apart from each other in the first direction D1.

The sacrificial layer 280 may include, e.g., polysilicon, the third mask 290 may include an insulating nitride, e.g., silicon nitride, and the fourth mask 300 may include, e.g., a photoresist pattern.

By the etching process, a fourth opening 310 may be formed between fourth stack structures, each of which may include the third and fourth masks 290 and 300 in the third direction D3, to extend in the second direction D2 and expose an upper surface of the sacrificial layer 280.

Referring to FIGS. 32 to 35, an etching process may be performed on the sacrificial layer 280 using the fourth stack structure as an etching mask so that the sacrificial layer 280 may be divided into a plurality of sacrificial patterns 285, each of which may extend in the second direction D2, spaced apart from each other in the first direction D1.

By the etching process, the fourth opening 310 may be enlarged downwardly to expose upper surfaces of the first insulation pattern 270 and the fourth gate insulation layer 260. The upper surface of the first insulation pattern 270 may be lower than the upper surface of the fourth gate insulation layer 260, so that a bottom of a portion of the fourth opening 310 exposing the upper surface of the first insulation pattern 270 may be lower than a bottom of a portion of the fourth opening 310 exposing the upper surface of the fourth gate insulation layer 260. That is, a depth of the portion of the fourth opening 310 on the first insulation pattern 270 may be greater than a depth of the portion of the fourth opening 310 on the fourth gate insulation layer 260.

The fourth mask 300 may be removed by, e.g., an ashing process and/or a stripping process.

The sacrificial pattern 285 and the third mask 290 sequentially stacked in the third direction D3 may collectively form a fifth stack structure.

Referring to FIGS. 36 to 39, second and third insulation layers may be sequentially stacked on the first insulation pattern 270 and the fourth gate insulation layer 260 to cover the fifth stack structure, a fourth insulation layer may be formed on the third insulation layer to fill the fourth opening 310, and a planarization process, e.g., a CMP process may be performed on the second to fourth insulation layers until the upper surface of the sacrificial pattern 285 is exposed.

Thus, the second to fourth insulation layers may be transformed into second to fourth insulation patterns 320, 330 and 340, respectively, extending in the second direction D2, and a sixth stack structure including the second to fourth insulation patterns 320, 330 and 340 may be formed between ones of the sacrificial patterns 285 neighboring in the first direction D1. A sidewall and a lower surface of the fourth insulation pattern 340 may be covered by the third insulation pattern 330, and an outer sidewall and a lower surface of the third insulation pattern 330 may be covered by the second insulation pattern 320.

As the depth of the portion of the fourth opening 310 on the first insulation pattern 270 is greater than a depth of the portion of the fourth opening 310 on the fourth gate insulation layer 260, when the second insulation layer is formed in the fourth opening 310 by a deposition process, the second insulation layer may entirely fill a lower portion of the portion of the fourth opening 310 on the first insulation pattern 270, and thus a thickness of a first portion of the second insulation pattern 330 on the first insulation pattern 270 may be greater than a second portion of the second insulation 330 on the fourth gate insulation layer 260.

Referring to FIGS. 40 to 43, the sacrificial pattern 285 may be removed by, e.g., a wet etching process to form a fifth opening exposing upper surfaces of the first insulation pattern 270 and the fourth gate insulation layer 260, a third conductive layer may be formed on the first insulation pattern 270, the fourth gate insulation layer 260 and the sixth stack structure to fill the fifth opening, and an upper portion of the third conductive layer by, e.g., an etch back process to form a plurality of third conductive lines 350, each of which may extend in the second direction D2, spaced apart from each other in the first direction D1.

A fifth insulation layer may be formed on the third conductive line 350 and the sixth stack structure 345 to fill the fifth opening, and a planarization process, e.g., a CMP process may be performed on the fifth insulation layer to form a plurality of fifth insulation patterns 360, each of which may extend in the second direction D2, spaced apart from each other in the first direction D1.

Referring to FIGS. 44 to 48, a second capping layer and a fifth mask layer may be sequentially stacked on the sixth stack structure 345 and the fifth insulation pattern 360, the fifth mask layer may be patterned to form a plurality of fifth masks 380, each of which may extend in the second direction D2, spaced apart from each other in the first direction D1, and an etching process may be performed on the second capping layer using the fifth masks 380 as an etching mask to form a plurality of second capping patterns 370, each of which may extend in the second direction D2, spaced apart from each other in the first direction D1.

Thus, a sixth opening 390 may be formed between ones of the second capping patterns 370 neighboring in the first direction D1 to extend in the second direction D2 and expose upper surfaces of a portion of the sixth stack structure 345 and portions of the fifth insulation pattern 360 at opposite sides in the first direction D1 of the sixth stack structure 345.

The fifth mask 380 may include, e.g., a photoresist pattern.

Referring to FIGS. 49 to 53, the fourth insulation pattern 340 included in a portion of the sixth stack structure exposed by the sixth opening 390 may be removed by, e.g., a wet etching process to expose an upper surface of a portion of the third insulation pattern 330, and the portion of the third insulation pattern 330 and portions of the second insulation pattern 320 and the second gate insulation layer structure 265 under the portion of the third insulation pattern 330 may be removed by, e.g., a wet etching process or a dry etching process to form a seventh opening 400 extending in the second direction D2 and exposing an upper surface of the channel layer 240.

Thus, a portion of the second gate insulation layer structure 265 exposed by the seventh opening 400 may not extend in the second direction D2, but may be divided into a plurality of parts spaced apart from each other in the second direction D2. Additionally, a portion of the fourth insulation pattern 340 exposed by the seventh opening 400 may not extend in the second direction D2, but may also be divided into a plurality of parts spaced apart from each other in the second direction D2.

As the thickness of the first portion of the second insulation pattern 330 on the first insulation pattern 270 is greater than the second portion of the second insulation 330 on the fourth gate insulation layer 260 including the fourth gate insulation layer 260, when the seventh opening 400 is formed, the first portion of the second insulation pattern 320 may not be entirely removed, and the upper surface of the first insulation pattern 270 may not be exposed by the seventh opening 400.

Referring to FIGS. 54 to 58, a fourth conductive layer may be formed on the channel layer 240, the sixth stack structure 345 and the fifth insulation pattern 360 to fill the seventh opening 400, a planarization process, e.g., a CMP process may be performed on the fourth conductive layer until the upper surface of the sixth stack structure 345 is exposed, and an upper portion of the fourth conductive layer may be removed by, e.g., a etch back process to form a fourth conductive line 410 extending in the second direction D2 in the lower portion of the seventh opening 400.

During the planarization process, the second capping pattern 370 may be removed.

Referring to FIGS. 59 to 63, a sixth insulation layer may be formed on the fourth conductive line 410, the sixth stack structure 345 and the fifth insulation pattern 360, a planarization process, e.g., a CMP process may be performed on the sixth insulation layer until an upper surface of the sixth stack structure 354 is exposed, a seventh insulation layer may be formed on the sixth insulation layer, and a sixth mask 430 may be formed on the seventh insulation layer.

In example embodiments, the sixth and seventh insulation layers may include substantially the same material as each other, and thus may be merged with each other, which may be referred to as an eighth insulation layer 420. The sixth mask 430 may include, e.g., a photoresist pattern.

An etching process may be performed using the sixth mask 430 as an etching mask to partially etch the eighth insulation layer 420, and thus an eighth opening 440 exposing an upper surface of the sixth stack structure 345 and a portion of the eighth insulation layer 420 adjacent thereto in the first direction D1 may be formed.

In example embodiments, a plurality of eighth openings 440 may be formed in each of the first and second directions D1 and D2, and each of the eighth openings 440 may expose an upper surface of the fourth insulation pattern 340 included in the sixth stack structure 345 and upper surfaces of portions of the second and third insulation patterns 320 and 330 at a side in the first direction D1 of the fourth insulation pattern 340.

Referring to FIGS. 64 to 68, the portion of the fourth insulation pattern 340 exposed by the eighth opening 440 and a portion of the third insulation pattern 330 thereunder may be removed by, e.g., a dry etching process to form a ninth opening 450 exposing an upper surface of a portion of the second insulation pattern 320, and for example, a wet etching process may be further performed to enlarge the ninth opening 450 in the horizontal direction.

During the dry etching process and/or the wet etching process, the sixth mask 430 may be removed.

Referring to FIGS. 69 to 73, the portion of the second insulation pattern 320 exposed by the ninth opening 450 and a portion of the second gate insulation layer structure 265 thereunder may be removed by, e.g., a wet etching process to form a tenth opening 460 exposing an upper surface of the channel layer 240.

During the wet etching process, an upper portion of the fourth insulation pattern 340 may also be removed.

Referring to FIGS. 74 to 78, a contact plug layer may be formed on the channel layer 240, the sixth stack structure 345 and the eighth insulation layer 420 to fill the tenth opening 460, a planarization process, e.g., a CMP process and an etch back process may be performed on the contact plug layer until the upper surfaces of the sixth stack structure 345 and the eighth insulation layer 420 are exposed to form a contact plug 470 in the tenth opening 460.

In example embodiments, the contact plug 470 may contact the upper surface of the channel layer 240, and a plurality of contact plugs 470 may be spaced apart from each other in each of the first and second directions D1 and D2.

Referring to FIGS. 1 to 5 again, a ninth insulation layer 490 may be formed on the eighth insulation layer 420 and the contact plug 470.

In example embodiments, the ninth insulation layer 490 may include substantially the same material as the eighth insulation layer 420, and thus the eighth and ninth insulation layers 420 and 490 may be merged with each other, which may be referred to as the ninth insulation layer 490.

A second mold layer may be formed on the ninth insulation layer 490, upper portions of the second mold layer and the ninth insulation layer 490 may be partially removed to form an eleventh opening exposing an upper surface of the contact plug 470, and a first capacitor electrode 500 may be formed in the eleventh opening. In example embodiments, a plurality of first capacitor electrodes 500 may be formed to be spaced apart from each other in each of the first and second directions D1 and D2.

The second mold layer may be removed, a dielectric layer 510 and a second capacitor electrode 520 may be sequentially formed on the ninth insulation layer 490 to cover the first capacitor electrode 500, and a plate electrode 540 may be formed on the second capacitor electrode 520 to fill a space between the first capacitor electrodes 500. The first and second capacitor electrodes 500 and 520 and the dielectric layer 510 therebetween may collectively form a capacitor 530.

By the above processes, the manufacturing of the semiconductor device may be completed.

As illustrated above, in example embodiments, after forming the channel layer 240, an etching process may not be performed on the channel layer 240 so that memory cells may be separated from each other, and thus the deterioration of the channel layer 240 due to the etching process may be limited and/or prevented.

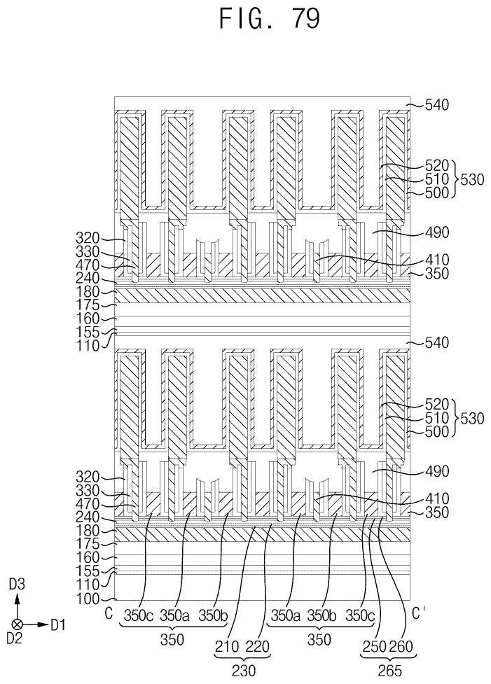

FIG. 79 is a cross-sectional view illustrating a semiconductor device in accordance with example embodiments.

Referring to FIG. 79, the semiconductor device may be manufactured by vertically stacking the semiconductor devices illustrated with reference to FIGS. 1 to 5, and for example, a lower circuit pattern may be formed on the substrate 100 to apply electrical signals to the memory cells.

FIG. 79 shows that the semiconductor device includes memory cell arrays stacked at two levels, however, inventive concepts may not be limited thereto, and may include memory cell arrays stacked at more than two levels.

The semiconductor device may have a 1T-1C cell structure including one transistor and one capacitor connected thereto, however, inventive concepts may not be limited thereto. For example, the semiconductor device may have 2T gain cell structure including one read transistor and one write transistor.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
a substrate;
word lines on the substrate, the word lines extending in a first direction, the first direction being parallel to an upper surface of the substrate, the word lines being spaced apart from each other in a second direction, the second direction being parallel to the upper surface of the substrate, and the second direction intersecting the first direction;
a channel layer on the word lines;
bit lines contacting an upper surface of the channel layer, the bit lines extending in the second direction and being spaced apart from each other in the first direction;
first conductive division lines on the channel layer and spaced apart from each other in the first direction, the first conductive division lines extending in the second direction between the bit lines;
contact plugs contacting the upper surface of the channel layer, the contact plugs being spaced apart from each other in the first direction and the second direction; and
capacitors on the contact plugs, respectively, wherein
the channel layer is divided into channels by the first conductive division lines and the channels are electrically insulated from each other in the first direction.

2. The semiconductor device according to claim 1, wherein the first conductive division lines are configured to maintain an off-state.

3. The semiconductor device according to claim 1, further comprising:
a first select line on the channel layer, wherein
the first select line extends in the second direction at a first side in the first direction of the bit lines.

4. The semiconductor device according to claim 3, wherein the first select line is between a corresponding one of the bit lines and a corresponding one of the first conductive division lines.

5. The semiconductor device according to claim 3, further comprising:
a second select line on the channel layer, wherein
the second select line extends in the second direction at a second side in the first direction of the bit lines.

6. The semiconductor device according to claim 5, wherein the second select line is between one of the bit lines and one of the first conductive division lines.

7. The semiconductor device according to claim 1, further comprising:
second conductive division lines spaced apart from each other in the second direction, wherein
the second conductive division lines extend in the first direction under the word lines on the substrate,
the channel layer is divided into a plurality of portions electrically insulated from each other in the second direction by the second conductive division lines.

8. The semiconductor device according to claim 7, wherein the second conductive division lines are configured to maintain an off-state.

9. The semiconductor device according to claim 7, wherein the second conductive division lines are between the word lines in a plan view.

10. The semiconductor device according to claim 9, wherein a portion of the channel layer on the second conductive division lines is lower than a portion of the channel layer on the word lines.

11. The semiconductor device according to claim 7, further comprising:
a gate insulation layer structure, wherein
the gate insulation layer structure contacts upper surfaces of the second conductive division lines, upper surfaces of the word lines, and a lower surface of the channel layer.

12. The semiconductor device according to claim 1, wherein
two of the contact plugs includes disposed in the first direction between a pair of neighboring bit lines in the first direction among the bit lines.

13. The semiconductor device according to claim 1, wherein
the contact plugs includes a first contact plug and a second contact plug respectively at opposite sides in the first direction of each corresponding bit line among the bit lines, and
the first contact plug and the second contact plug are symmetrically disposed with reference to the corresponding bit line.

14. A semiconductor device comprising:
a substrate;
first conductive division lines on a substrate, the first conductive division lines extending in a first direction, the first direction being parallel to an upper surface of the substrate, the first conductive division lines being spaced apart from each other in a second direction, the second direction being parallel to the upper surface of the substrate, and the second direction intersecting the first direction;
word lines spaced apart from each other in the second direction on the first conductive division lines, the word lines extending in the first direction;
a channel layer on the first conductive division lines and the word lines;
bit lines contacting an upper surface of the channel layer, the bit lines extending in the second direction, and the bit lines being spaced apart from each other in the first direction;
contact plugs contacting the upper surface of the channel layer, the contact plugs being spaced apart from each other in the first direction and the second direction; and
capacitors on the contact plugs, respectively,
wherein the channel layer is divided into channels that are electrically insulated from each other in the first direction by the first conductive division lines.

15. The semiconductor device according to claim 14, wherein the first conductive division lines are configured to maintain an off-state.

16. The semiconductor device according to claim 14, further comprising:
a gate insulation layer structure contacting upper surfaces of the first conductive division lines, upper surface of the word lines, and a lower surface of the channel layer.

17. The semiconductor device according to claim 14, further comprising:
second conductive division lines spaced apart from each other in the first direction, wherein
the second conductive division lines extend in the second direction between the bit lines on the channel layer, and
the channel layer is divided into a plurality of portions electrically insulated from each other in the first direction by the second conductive division lines.

18. The semiconductor device according to claim 17, further comprising:
a first select line on the channel layer, the first select line extending in the second direction at a first side in the first direction of the bit lines; and
a second select line on the channel layer, the first select line extending in the second direction at a second side in the first direction of the bit lines, wherein
a corresponding one of the first selecting lines and a corresponding one of the second select lines are between a corresponding one of the bit lines and a corresponding one of the second conductive division lines.

19. A semiconductor device comprising:
a substrate;
first conductive division lines on the substrate, the first conductive division lines extending in a first direction, the first direction being parallel to an upper surface of the substrate, the first conductive division lines being spaced apart from each other in a second direction, the second direction being parallel to the upper surface of the substrate, and the second direction intersecting the first direction;
word lines spaced apart from each other in the second direction on the first conductive division lines, the word lines extending in the first direction;
a channel layer on the first conductive division lines and the word lines;
bit lines contacting an upper surface of the channel layer, the bit lines extending in the second direction, and the bit lines being spaced apart from each other in the first direction;
second conductive division lines spaced apart from each other in the first direction, the second conductive division lines extending in the second direction between the bit lines on the channel layer;
contact plugs contacting the upper surface of the channel layer, the contact plugs being spaced apart from each other in the first direction and the second direction; and
capacitors on the contact plugs, respectively,
wherein the channel layer is divided into channels that are electrically insulated from each other in the first direction and the second direction by the first conductive division lines and the second conductive division lines.

20. The semiconductor device according to claim 19, further comprising:
a first select line on the channel layer, the first select line extending in the second direction at a first side in the first direction of the bit lines; and
a second select line on the channel layer, the first select line extending in the second direction at a second side in the first direction of the bit lines, wherein
a corresponding one of the first select lines and a corresponding one of the second select lines are between a corresponding one of the bit lines and a corresponding one of the second conductive division lines.
